(19) United States
(12) Patent Application Publication
(10) Pub. No.: US 2026/0101647 A1
(43) Pub. Date: Apr. 9, 2026

(54) DISPLAY SUBSTRATE AND DISPLAY DEVICE

(71) Applicants: CHENGDU BOE OPTOELECTRONICS TECHNOLOGY CO., LTD., Chengdu, SC (US); BOE TECHNOLOGY GROUP CO., LTD., Beijing (CN)

(72) Inventors: Rui ZHOU, Beijing (CN); Quan SHI, Beijing (CN); Wei ZHANG, Beijing (CN); Chengjie QIN, Beijing (CN); Yanwei LU, Beijing (CN); Xiaoliang GUO, Beijing (CN); Lili DU, Beijing (CN); Cong LIU, Beijing (CN); Benlian WANG, Beijing (CN); Weiyun HUANG, Beijing (CN)

(21) Appl. No.: 19/405,897

(22) Filed: Dec. 2, 2025

Related U.S. Application Data
(63) Continuation of application No. 19/021,856, filed on Jan. 15, 2025.
Application No. 19/021,856 is a continuation of application No. 18/578,514.

(30) Foreign Application Priority Data
Nov. 30, 2021 (CN) 202111450504.X

(51) Int. Cl. H10K 59/122; H10K 59/12; H10K 59/126; H10K 59/131

(52) U.S. Cl. CPC H10K 59/122; H10K 59/1201; H10K 59/126; H10K 59/131

(57) ABSTRACT

A display substrate and a display device. The display substrate includes a substrate base, a plurality of sub-pixels, and a partition structure; the partition structure includes a plurality of annular partition parts, which include a plurality of first annular partition parts, a plurality of second annular partition parts, and a plurality of third annular partition parts, the first annular partition part is around one second color sub-pixel, the second annular partition part is around one first color sub-pixel, the third annular partition part is around one third color sub-pixel, each of the plurality of first annular partition parts includes a first number of first notches, each of the plurality of second annular partition parts includes a second number of second notches, each of the plurality of third annular partition parts includes a third number of third notches, the second number is different from the third number.

The present application is a continuation of U.S. Ser. No. 19/021,856 filed on Jan. 15, 2025, which is a continuation of U.S. Ser. No. 18/578,514 filed on Jan. 11, 2024, which is a national stage application of PCT international patent application No. PCT/CN2022/124653, filed on Oct. 11, 2022, which claims priority to the Chinese Patent Application No. 202111450504.X filed on Nov. 30, 2021. All the aforementioned patent applications are hereby incorporated by reference in their entireties.

### TECHNICAL FIELD

Embodiments of the present disclosure relate to a display substrate and a display device.

### BACKGROUND

With the continuous development of display technology, organic light-emitting diode display devices (OLED) have become the research focus and technical development direction of present major manufacturers because of the advantages thereof, such as wide color gamut, high contrast, slim design, self-luminescence and wide viewing angle.

At present, organic light-emitting diode display devices (OLED) have been widely used in various electronic products, ranging from some small electronic products, such as smart bracelets, smart watches, smart phones, tablet computers, and so on, to some large type electronic products, such as notebook computers, desktop computers, televisions, and so on. Therefore, the market demand for active matrix organic light-emitting diode display devices is also growing.

### SUMMARY

Embodiments of the present disclosure provide a display substrate and a display device. The display substrate includes a base substrate, a plurality of sub-pixels and a partition structure; the plurality of sub-pixels are on the base substrate, and each sub-pixel includes a light-emitting element, the light-emitting element includes a light-emitting function layer, and a first electrode and a second electrode that are respectively located on two sides of the light-emitting function layer, the second electrode is located between the light-emitting function layer and the base substrate, and the light-emitting function layer includes a charge generation layer; the partition structure is located on the base substrate, between adjacent sub-pixels, and the charge generation layer of the light-emitting function layer is disconnected at the position where the partition structure is located. Therefore, the display substrate, by providing the partition structure between adjacent sub-pixels and allowing the charge generation layer of the light-emitting function layer to be disconnected at the position where the partition structure is located, can avoid the crosstalk between adjacent sub-pixels caused by the charge generation layer with a relative high conductivity.

At least one embodiment of the present disclosure provides a display substrate, which includes: a base substrate; a plurality of sub-pixels, on the base substrate, each of the plurality of sub-pixels includes a light-emitting element, the light-emitting element includes a light-emitting function layer, and a second electrode and a first electrode that are respectively on two sides of the light-emitting function layer, and the first electrode is between the light-emitting function layer and the base substrate, and the light-emitting function layer includes a conductive sub-layer; and a partition structure, on the base substrate, the partition structure is between adjacent ones of the plurality of sub-pixels, and the conductive sub-layer in the light-emitting function layer is disconnected at a position where the partition structure is located.

For example, in the display substrate provided by an embodiment of the present disclosure, the partition structure includes: a first sub-partition structure; and a second sub-partition structure, the first sub-partition structure and the second sub-partition structure are sequentially arranged in an arrangement direction of adjacent ones of the plurality of sub-pixels.

For example, the display substrate provided by an embodiment of the present disclosure further includes: a pixel definition layer, on the base substrate, part of the pixel definition layer is on a side of the first electrode away from the base substrate, and the pixel definition layer includes a plurality of pixel openings and a pixel spacing opening, the plurality of pixel openings are in one-to-one correspondence to the plurality of sub-pixels to define effective light-emitting regions of the plurality of sub-pixels, and each of the plurality of pixel openings is configured to expose the first electrode, the pixel spacing opening is between adjacent ones of the plurality of sub-pixels, and at least part of the partition structure is in the pixel spacing opening.

For example, in the display substrate provided by an embodiment of the present disclosure, the plurality of sub-pixels includes a plurality of first color sub-pixels, a plurality of second color sub-pixels and a plurality of third color sub-pixels, the partition structure includes a plurality of annular partition parts, each of the plurality of annular partition parts surrounds one selected from a group consisting of one of the plurality of first color sub-pixels, one of the plurality of second color sub-pixels and one of the plurality of third color sub-pixels.

For example, in the display substrate provided by an embodiment of the present disclosure, the plurality of annular partition parts include a plurality of first annular partition parts, and each of the plurality of first annular partition parts is around one of the plurality of second color sub-pixels.

For example, in the display substrate provided by an embodiment of the present disclosure, each of the plurality of first annular partition parts includes at least one first notch.

For example, in the display substrate provided by an embodiment of the present disclosure, the partition structure further includes: a plurality of first strip-shaped partition parts, each of the plurality of first strip-shaped partition parts extends along a first direction; and a plurality of second strip-shaped partition parts, each of the plurality of second strip-shaped partition parts extends along a second direction; each of the plurality of first strip-shaped partition parts connects two first annular partition parts adjacent in the first direction, and each of the plurality of the second strip-shaped partition parts connects two first annular partition parts adjacent in the second direction, the plurality of first strip-shaped partition parts and the plurality of second strip-shaped partition parts connect the plurality of first annular partition parts to form a plurality of first grid structures and a plurality of second grid structures in a region other than the plurality of first annular partition parts, and each of the plurality of first grid structures is around one of the plurality of first color sub-pixels and the each of plurality of second grid structures is around one of the plurality of third color sub-pixels.

For example, the display substrate provided by an embodiment of the present disclosure further includes: a spacer, the plurality of first strip-shaped partition parts and the plurality of second strip-shaped partition parts connect the plurality of first annular partition parts to further form a plurality of third grid structures, and each of plurality of the third grid structures is around one of the plurality of first color sub-pixels and one of the plurality of third color sub-pixels that are adjacent to each other, and the spacer is within the third grid structure and between the one of the plurality of first color sub-pixels and the one of the plurality of third color sub-pixels.

For example, the display substrate provided by an embodiment of the present disclosure further includes: a spacer, the spacer is within one of the plurality of first grid structures or one of the plurality of second grid structures, and is between one of the plurality of first color sub-pixels and one of the plurality of third color sub-pixels that are adjacent to each other.

For example, in the display substrate provided by an embodiment of the present disclosure, the partition structure further includes: a plurality of second annular partition parts, each of the plurality of second annular partition parts is around one of the plurality of first color sub-pixels; and a plurality of third annular partition parts, each of the plurality of the third annular partition parts is around one of the plurality of third color sub-pixels.

For example, in the display substrate provided by an embodiment of the present disclosure, the partition structure further includes: a plurality of second annular partition parts, each of plurality of second annular partition parts is around one of the plurality of first color sub-pixels; and a plurality of third annular partition parts, each of plurality of is around one of the plurality of third color sub-pixels, each of the plurality of third annular partition parts includes a second notch, and two ends of the third annular partition part at the second notch are respectively connected with two first annular partition parts adjacent in the first direction or the second direction.

For example, the display substrate provided by an embodiment of the present disclosure further includes: a spacer, the spacer is at the second notch of one of the plurality of third annular partition parts.

For example, in the display substrate provided by an embodiment of the present disclosure, the plurality of first color sub-pixels and the plurality of third color sub-pixels are alternately arranged along both the first direction and the second direction to form a plurality of first pixel rows and a plurality of first pixel columns, and the plurality of second color sub-pixels are arranged in an array along both the first direction and the second direction to form a plurality of second pixel rows and a plurality of second pixel columns, the plurality of first pixel rows and the plurality of second pixel rows are alternately arranged along the second direction and staggered in the first direction, the plurality of first pixel columns and the plurality of second pixel columns are alternately arranged along the first direction and staggered in the second direction, the partition structure is between one of the plurality of first color sub-pixels and one of the plurality of third color sub-pixels that are adjacent to each other, and/or, the partition structure is between one of the plurality of second color sub-pixels and one of the plurality of third color sub-pixels that are adjacent to each other, and/or, between one of the plurality of first color sub-pixels and one of the plurality of second color sub-pixels that are adjacent to each other.

For example, in the display substrate provided by an embodiment of the present disclosure, the plurality of sub-pixels includes a plurality of first color sub-pixels, a plurality of second color sub-pixels and a plurality of third color sub-pixels, the partition structure includes a plurality of first annular partition parts, and each of the plurality of first annular partition parts is around two adjacent ones of the plurality of second color sub-pixels.

For example, in the display substrate provided by an embodiment of the present disclosure, the partition structure further includes: a plurality of second annular partition parts, each of the plurality of second annular partition parts is around one of the plurality of first color sub-pixels; and a plurality of third annular partition parts, each of plurality of third annular partition parts is around one of the plurality of third color sub-pixels.

For example, in the display substrate provided by an embodiment of the present disclosure, any two adjacent annular partition parts selected from a group consisting of the plurality of first annular partition parts, the plurality of second annular partition parts and the plurality of third annular partition parts share a partition edge part.

For example, in the display substrate provided by an embodiment of the present disclosure, the plurality of sub-pixels are divided into a plurality of sub-pixel groups, and each of the plurality of sub-pixel groups includes one of the plurality of first color sub-pixels, two of the plurality of second color sub-pixels and one of the plurality of third color sub-pixels, in each sub-pixel group, the one of the plurality of first color sub-pixels and the one of the plurality of third color sub-pixels are arranged along a first direction, and the two of the plurality of second color sub-pixels are arranged in a second direction and adjacent to each other, and are between the one of the plurality of first color sub-pixels and the one of the plurality of third color sub-pixels.

For example, in the display substrate provided by an embodiment of the present disclosure, the partition structure includes: a groove; a shielding part, the shielding part is at an edge of the groove and protrudes into the groove to form a protrusion part covering a part of an opening of the groove, and the conductive sub-layer of the light-emitting function layer is disconnected at the protrusion part of the shielding part.

For example, in the display substrate provided by an embodiment of the present disclosure, two edges, in an arrangement direction of two adjacent ones of the plurality of sub-pixels, of the groove are respectively provided with the shielding part.

For example, in the display substrate provided by an embodiment of the present disclosure, the partition structure includes a partition column, the partition column includes a first isolation part and a second isolation part that are stacked with each other, the first isolation part is at a side of the second isolation part close to the base substrate, the second isolation part includes a protrusion part beyond the first isolation part in an arrangement direction of two adjacent ones of the plurality of sub-pixels, and the conductive sub-layer of the light-emitting function layer is disconnected at a position where the protrusion part of the second isolation part is located.

For example, in the display substrate provided by an embodiment of the present disclosure, the light-emitting function layer includes a first light-emitting layer and a second light-emitting layer that are respectively on two sides of the conductive sub-layer in a direction perpendicular to the base substrate, and the conductive sub-layer is a charge generation layer.

For example, in the display substrate provided by an embodiment of the present disclosure, the second electrode is disconnected at the position where the partition structure is located.

For example, the display substrate provided by an embodiment of the present disclosure further includes: a planarization layer, at a side of the first electrode close to the base substrate; a plurality of data lines, between the planarization layer and the base substrate, the data lines extend along a first direction and arranged along a second direction, and the first direction intersect the second direction; a plurality of power lines, between the planarization layer and the base substrate, the plurality of power lines extend along the first direction and are arranged in the second direction, and the partition structure overlaps, in the direction perpendicular to the base substrate, with at least one of the data line and the power line.

At least one embodiment of the present disclosure further provides a display device, which includes any one of the abovementioned display substrates.

### BRIEF DESCRIPTION OF DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a schematic planar view of a display substrate provided by an embodiment of the present disclosure;

FIG. 2 is a schematic cross-sectional view of a display substrate taken along the direction AB in FIG. 1 provided by an embodiment of the present disclosure;

FIG. 3 is a schematic planar view of another display substrate provided by an embodiment of the present disclosure;

FIG. 4 is a schematic planar view of another display substrate provided by an embodiment of the present disclosure;

FIG. 5 is a schematic cross-sectional view of a display substrate along the direction CD in FIG. 4 provided by an embodiment of the present disclosure;

FIG. 6 is a schematic planar view of further another display substrate provided by an embodiment of the present disclosure;

FIG. 7 is a schematic planar view of further another display substrate provided by an embodiment of the present disclosure;

FIG. 8 is a schematic planar view of further another display substrate provided by an embodiment of the present disclosure;

FIG. 9 is a schematic planar view of further another display substrate provided by an embodiment of the present disclosure;

FIG. 10 is a schematic planar view of further another display substrate provided by an embodiment of the present disclosure;

FIG. 11 is a schematic planar view of further another display substrate provided by an embodiment of the present disclosure;

FIG. 12 is a schematic planar view of further another display substrate provided by an embodiment of the present disclosure;

FIG. 13 is a partial cross-sectional view of a display substrate provided by an embodiment of the present disclosure;

FIG. 14 is a schematic diagram of a display device provided by an embodiment of the present disclosure;

FIG. 15 is a schematic planar view of further another display substrate provided by an embodiment of the present disclosure;

FIG. 16 is a schematic cross-sectional view of a display substrate taken along the line EF in FIG. 15 provided by an embodiment of the present disclosure;

FIG. 17A is a partial cross-sectional view of further another display substrate provided by an embodiment of the present disclosure;

FIG. 17B is a cross-sectional electron microscope view of a display substrate provided by an embodiment of the present disclosure;

FIG. 18 is a schematic diagram of further another display device provided by an embodiment of the present disclosure;

FIG. 19 is a partial cross-sectional view of a display substrate provided by an embodiment of the present disclosure;

FIG. 20 is a schematic cross-sectional view of a partial structure of a display substrate provided by another example of an embodiment of the present disclosure;

FIG. 21A is a schematic cross-sectional view of a partial structure of a display substrate provided by further another example of an embodiment of the present disclosure;

FIG. 21B is a schematic cross-sectional view of a partial structure of a display substrate provided by further another example of an embodiment of the present disclosure;

FIG. 22A to FIG. 22D are flow charts of a manufacturing method of the display substrate before forming the display substrate shown in FIG. 19;

FIG. 23 is a schematic cross-sectional view of a partial structure of a display substrate provided by another example of an embodiment of the present disclosure;

FIG. 24A to FIG. 24D are schematic flow charts of the manufacturing method of the display substrate before forming the display substrate shown in FIG. 23;

FIG. 25 is a schematic view of a partial cross-sectional structure of a display substrate provided by another example of an embodiment of the present disclosure;

FIG. 26 is a structural schematic diagram of further another display substrate provided by an embodiment of the present disclosure;

FIG. 27 is a structural schematic diagram of further another display substrate provided by an embodiment of the present disclosure;

FIG. 28 is a structural diagram of further another display substrate provided by an embodiment of the present disclosure;

FIG. 29 is a structural diagram of further another display substrate provided by an embodiment of the present disclosure;

FIG. 30A-FIG. 30C are schematic steps of another manufacturing method of a display substrate provided by an embodiment of the present disclosure; and

FIG. 31A-FIG. 31C are schematic steps of further another manufacturing method of a display substrate provided by an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms “comprise,” “comprising,” “comprise,” “comprising,” etc., are intended to specify that the elements or the objects stated before these terms encompass the elements or the objects and equivalents thereof listed after these terms, but do not preclude the other elements or objects.

The features such as “parallel”, “vertical” and “identical” used in the embodiments of the present disclosure all include the features such as “parallel”, “vertical” and “identical” in the strict sense, and include the situations such as “approximately parallel”, “approximately vertical” and “approximately identical” contain certain errors, considering the errors of the measurement method and the errors related to the measurement of a specific quantity (for example, the limitation of the measurement system), the above-mentioned features are expressed within the acceptable deviation range for a specific value determined by an ordinary person skilled in the art. For example, the feature “approximately” can mean the measurement error is within one or more standard deviations, or within 10% or 5% of the stated value. In the case that the quantity of a component is not specified in the following embodiment of the present disclosure, it refers that the component may be one or more, or may be understood as at least one. “At least one” refers one or more, and “a plurality of” refers at least two. “one same layer” in the embodiment of the present disclosure refers to the relationship between a plurality of layers formed by the same material after the same step (for example, one patterning process). The feature “same layer” here does not always mean that the thickness of the plurality of layers are the same or the heights of the plurality of layers in a cross-section view thereof are the same.

With the continuous development of display technology, people's pursuit of display quality is getting higher and higher. In order to further reduce power consumption and achieve high brightness, a single light-emitting layer in the light-emitting element in OLED can be replaced by two light-emitting layers, and a charge generation layer (CGL) is added between the two light-emitting layers to realize a design of Tandem EL. Because a display device with a design of Tandem EL has two light-emitting layers, its light-emitting brightness can be approximately equivalent to twice that of a single light-emitting layer. Therefore, the display device with the design of Tandem EL has the advantages of long life, low power consumption and high brightness.

However, the inventor(s) of this application noticed that for a high-resolution product, because the charge generation layer has a strong conductivity and the light-emitting function layers (here, the layers including two light-emitting layers and the charge generation layer) of adjacent sub-pixels are connected, the charge generation layer can easily lead to crosstalk between adjacent sub-pixels, thus seriously affecting the display quality.

In this regard, embodiments of the present disclosure provide a display substrate and a display device. The display substrate includes a base substrate, a plurality of sub-pixels and a partition structure; the plurality of sub-pixels are on the base substrate, and each sub-pixel includes a light-emitting element, the light-emitting element includes a light-emitting function layer, and a first electrode and a second electrode that are respectively located on two sides of the light-emitting function layer, the second electrode is located between the light-emitting function layer and the base substrate, and the light-emitting function layer includes a charge generation layer; the partition structure is located on the base substrate, between adjacent sub-pixels, and the charge generation layer of the light-emitting function layer is disconnected at the position where the partition structure is located. Therefore, the display substrate, by providing the partition structure between adjacent sub-pixels and allowing the charge generation layer of the light-emitting function layer to be disconnected at the position where the partition structure is located, can avoid the crosstalk between adjacent sub-pixels caused by the charge generation layer with a relative high conductivity.

Hereinafter, the display substrate and the display device provided by the embodiments of the present disclosure will be described in detail with reference to the drawings.

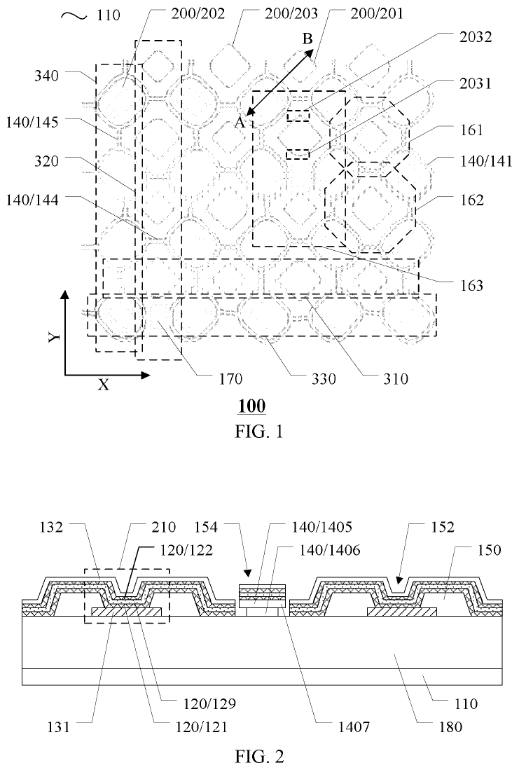

An embodiment of the present disclosure provides a display substrate. FIG. 1 is a schematic planar view of a display substrate provided by an embodiment of the present disclosure; FIG. 2 is a schematic cross-sectional view of a display substrate taken along the direction AB in FIG. 1 provided by an embodiment of the present disclosure.

As illustrated by FIG. 1 and FIG. 2, the display substrate 100 includes a base substrate 110 and a plurality of sub-pixels 200; the plurality of sub-pixels 200 are located on the base substrate 110, and each sub-pixel 200 includes a light-emitting element 210; each light-emitting element 210 includes a light-emitting function layer 120, and a first electrode 131 and a second electrode 132 that are respectively located on two sides of the light-emitting function layer 120, the first electrode 131 is located between the light-emitting function layer 120 and the base substrate 110. At least a part of the second electrode 132 is located on the side of the light-emitting function layer 120 away from the first electrode 131; that is, the first electrode 131 and the second electrode 132 are located on two sides of the light-emitting function layer 120 in the direction perpendicular to the light-emitting function layer 120. The light-emitting function layer 120 includes a plurality of sub-function layers, and the sub-function layers include a conductive sub-layer 129 with relative high conductivity. It should be noted that the above-mentioned feature “light-emitting function layer” include not only a layer that directly emits light, but also a functional layer that is used to assist light emission, such as a hole transport layer and an electron transport layer.

For example, the conductive sub-layer 129 may be a charge generation layer. For example, the first electrode 131 may be an anode and the second electrode 132 may be a cathode. For example, the cathode may be made of a material with high conductivity and low work function, and for example, the cathode may be made of a metal material. For example, the anode may be formed of a transparent conductive material with a high work function.

As illustrated by FIG. 1 and FIG. 2, the display substrate 100 further includes a partition structure 140, the partition structure 140 is located on the base substrate 110 and between adjacent sub-pixels 200; the charge generation layer 129 in the light-emitting function layer 120 is disconnected at the position where the partition structure 140 is located. It should be noted that the charge generation layer of the light-emitting function layer has a discontinuous structure or a non-integrated structure at the position where the charge generation layer is disconnected.

In the display substrate provided by the embodiment of the present disclosure, by providing the partition structure between adjacent sub-pixels, and allowing the charge generation layer of the light-emitting function layer to be disconnected at the position where the partition structure is located, the display substrate can avoid the crosstalk between adjacent sub-pixels caused by the charge generation layer with relative high conductivity. On the other hand, because the display substrate can avoid crosstalk between adjacent sub-pixels through the partition structure, the display substrate can improve pixels per inch while the display substrate adopts a design of Tandem EL. Therefore, the display substrate has the advantages of long service life, low power consumption, high brightness and high resolution.

In some examples, the feature “adjacent sub-pixels” refers that no other sub-pixel is disposed between the adjacent two sub-pixels.

In some examples, as illustrated by FIG. 1 and FIG. 2, the connection line of the brightness centers of two adjacent sub-pixels 200 passes through the partition structure 140. Because the size of the charge generation layer in the extension direction of the connection line is small, the resistance of the charge generation layer in the extension direction of the connection line is also small, and the charge is easily transferred from one of the two adjacent sub-pixels to the other of the two adjacent sub-pixels through the charge generation layer in the extension direction of the connection line. Therefore, in the display substrate, the connection line passes through the partition structure, which can effectively block the shortest propagation path of charges, thus effectively avoiding crosstalk between adjacent sub-pixels. It should be noted that the brightness center of each sub-pixel may be the geometric center of the effective light-emitting region of the sub-pixel. Of course, the embodiments of the present disclosure include, but are not limited to this case, and the brightness center of each sub-pixel may also be the position, where the light-emitting brightness of the sub-pixel is the maximum value, is located.

In some examples, as illustrated by FIG. 1 and FIG. 2, the display substrate 100 further includes a pixel definition layer 150 located on the base substrate 110; a part of the pixel definition layer 150 is located on the side of the first electrode 131 away from the base substrate 110; the pixel definition layer 150 includes a plurality of pixel openings 152 and pixel space openings 154; the plurality of pixel openings 152 are in one-to-one correspondence with the plurality of sub-pixels 200 to define effective light-emitting regions of the plurality of sub-pixels 200; each pixel opening 152 is configured to expose the respective first electrode 131 so that the first electrode 131 is in contact with the subsequently formed light-emitting function layer 120. The pixel spacing opening 154 is located between adjacent first electrodes 131, and at least part of the partition structure 140 is located in the pixel spacing opening 154. Therefore, the display substrate can avoid forming the partition structure on the pixel definition layer, thereby avoiding increasing the thickness of the display substrate. Of course, the embodiments of the present disclosure include but are not limited to this case, and the pixel definition layer may not be provided with the above-mentioned pixel spacing opening, so that the partition structure may be directly arranged on the pixel definition layer, or the partition structure may be formed by using the pixel definition layer.

For example, the material of the pixel definition layer may include an organic material, such as polyimide, acrylic or polyethylene terephthalate.

In some examples, as illustrated by FIG. 2, the partition structure 140 may be a partition column; in this case, the partition structure 140 includes a first isolation part 1405 and a second isolation part 1406 which are stacked with each other, and the first isolation part 1405 is located at the side of the second isolation part 1406 close to the base substrate 110; the second isolation part 1406 has a protrusion part 1407 beyond the first isolation part 1405 in the arrangement direction of two adjacent sub-pixels 200, and the conductive sub-layer 129 of the light-emitting function layer 120 is disconnected at the position where the protrusion part 1407 is located. Therefore, the partition structure can realize the disconnection of the conductive sub-layer of the light-emitting function layer. It should be noted that the partition structure provided by the embodiment of the present disclosure is not limited to the above-mentioned partition column, and other structures that can realize the disconnection of the conductive sub-layer of the light-emitting function layer may also be adopted. In addition, the above arrangement direction may be the extension direction of the connection line of the brightness centers of two adjacent sub-pixels.

In some examples, as illustrated by FIG. 2, a plurality of sub-pixels 200 share the second electrode 132, and the second electrode 132 is disconnected at the position where the partition structure 140 is located. However, embodiments of the present disclosure include but are not limited to this case, and the second electrode may be continuously and not disconnected at the position where the partition structure is located.

In some examples, as illustrated by FIG. 2, the light-emitting function layer 120 includes a first light-emitting layer 121 and a second light-emitting layer 122 that are respectively located on two sides of the conductive sub-layer 129 in the direction perpendicular to the base substrate 110, and the conductive sub-layer 129 is a charge generation layer. Therefore, the display substrate can realize a Design of Tandem EL, so that the display substrate has the advantages of long life, low power consumption and high brightness.

In some examples, as illustrated by FIG. 2, the first light-emitting layer 121 and the second light-emitting layer 122 in the light-emitting function layer 120 are also disconnected at the position where the partition structure 140 is located. However, the embodiments of the present disclosure include but are not limited to this case, and the first light-emitting layer and the second light-emitting layer in the light-emitting function layer may not be disconnected at the position where the partition structure is located, and only the conductive sub-layer may be disconnected at the position where the partition structure is located.

In some examples, the conductivity of the conductive sub-layer 129 is greater than that of the first light-emitting layer 121 and the second light-emitting layer 122, and less than that of the second electrode 132.

For example, as illustrated by FIG. 2, the first light-emitting layer 121 is located on the side of the conductive sub-layer 129 close to the base substrate 110; the second light-emitting layer 122 is located on the side of the conductive sub-layer 129 away from the base substrate 110.

It should be noted that the light-emitting function layer may also include other sub-function layers besides the conductive sub-layer, the first light-emitting layer and the second light-emitting layer, for example, a hole injection layer, a hole transport layer, an electron injection layer and an electron transport layer.

For example, the materials of the first light-emitting layer and the second light-emitting layer may be selected from a group consisting of pyrene derivatives, anthracene derivatives, fluorene derivatives, perylene derivatives, styrylamine derivatives, metal complexes, and the like.

For example, the material of the hole injection layer may include oxides, such as molybdenum oxide, titanium oxide, vanadium oxide, rhenium oxide, ruthenium oxide, chromium oxide, zirconium oxide, hafnium oxide, tantalum oxide, silver oxide, tungsten oxide, and manganese oxide.

For example, the material of the hole injection layer may also include an organic material, such as hexacyanohexaazatriphenyl, 2,3,5,6-tetrafluoro-7,7,8,8-tetracyanoquinodimethane (F4TCNQ), 1,2,3-tri [(cyano) (4-cyano-2,3,5,6-tetrafluorophenyl) methylene] cyclopropane.

For example, the material of the hole transport layer may include aromatic amines, or dimethyl fluorene material or carbazole material that are with hole transport characteristics, such as 4 ,4′-bis [N-(1-naphthyl)-N-phenylamino] biphenyl (NPB), N, N′-bis (3-methylphenyl)-N, N′-diphenyl-[1,1′-biphenyl]-4, 4′-diamine (TPD), 4-phenyl-4′-(9-phenylfluorene-9-yl) triphenylamine (BAFLP), 4,4′-bis [N-(9,9-dimethylfluorene-2-yl)-N-phenylamino] biphenyl (DFLDPBi), 4,4′-bis (9-carbazolyl) biphenyl (CBP), 9-phenyl-3-[4-(10- phenyl-9- anthracenyl) phenyl ]-9H-carbazole (PCzPA).

For example, the material of the electron transport layer may include aromatic heterocyclic compounds, such as benzimidazole derivatives, imidazole derivatives, pyrimidine derivatives, azine derivatives, quinoline derivatives, isoquinoline derivatives, phenanthroline derivatives, and the like.

For example, the material of the electron injection layer may be alkali metal or metal and their compounds, such as lithium fluoride (LiF), ytterbium (Yb), magnesium (Mg) and calcium (Ca).

In some examples, the first electrode 131 may adopt a metal material, such as any one or more selected from a group consisting of magnesium (Mg), silver (Ag), copper (Cu), aluminum (Al), titanium (Ti), and molybdenum (Mo), or, an alloy material of the above metals, such as aluminum-neodymium alloy (AlNd) or molybdenum-niobium alloy (MoNb), may be a single-layer structure, or a multi-layer composite structure, such as Ti/Al/Ti, or a stacked structure constituted by metal and transparent conductive materials, for example, a reflective material such as ITO/Ag/ITO, Mo/AlNd/ITO, and the like.

In some examples, the second electrode 132 may be made of any one or more selected from a group consisting of magnesium (Mg), silver (Ag) and aluminum (Al), or may be an alloy made of any one or more of the above metals, or a transparent conductive material, such as indium tin oxide (ITO), or a multilayer composite structure constituted by metal and transparent conductive material.

In some examples, the charge generation layer 129 may be configured to generate carriers, transport carriers, and inject carriers. For example, the material of the charge generation layer 129 may include an N-doped organic layer/inorganic metal oxide, such as Alq3Mg/WO3, Bphen Li/MoO3, BCP:Li/V2O5 and BCP:Cs/V2O5; or, an n-type doped organic layer/organic layer, such as Alq3:Li/HAT-CN; or, n-type doped organic layer/p-type doped organic layer, such as BPhen: Cs/NPB:F4-TCNQ, Alq3:Li/NPB:FeCl3, TPBi:Li/NPB:FeCl3 and Alq3:Mg/m-MTDATA:F4-TCNQ; or, undoped, such as F16CuPc/CuPc and Al/WO3/Au.

In some examples, the material of the base substrate 110 may be made of one or more materials selected from a group consisting of glass, polyimide, polycarbonate, polyacrylate, polyetherimide and polyethersulfone, and this embodiment includes but is not limited to this case.

In some examples, the base substrate may be a rigid substrate or a flexible substrate; in the case that the base substrate is a flexible substrate, the base substrate may include a first flexible material layer, a first inorganic material layer, a semiconductor layer, a second flexible material layer and a second inorganic material layer which are sequentially stacked. The materials of the first flexible material layer and the second flexible material layer are polyimide (PI), or polyethylene terephthalate (PET) or polymer soft film after being performed a surface treatment, etc. The materials of the first inorganic material layer and the second inorganic material layer are silicon nitride (SiNx) or silicon oxide (SiOx) which are used to improve the water-oxygen resistance of the base substrate. The first inorganic material layer and the second inorganic material layer are also called barrier layers. The material of the semiconductor layer is amorphous silicon (a-Si).

For example, the case that the base substrate is a stacked structure of PI1/Barrier1/a-si/PI2/Barrier2 is taken as an example, the preparation process of the base substrate includes: coating a polyimide layer on a glass carrier plate, curing the polyimide layer to form into a film, and then forming a first flexible layer (PI1); subsequently, depositing a barrier film on the first flexible layer to form a first barrier layer (Barrier1) covering the first flexible layer; then depositing an amorphous silicon film on the first barrier layer to form an amorphous silicon layer (a-Si) covering the first barrier layer; then coating a polyimide layer on the amorphous silicon layer, and curing this polyimide layer to form into a film so as to form a second flexible layer (PI2); then, a barrier film is deposited on the second flexible layer to form a second barrier layer (Barrier2) covering the second flexible layer, and finally the preparation of the base substrate is completed.

In some examples, as illustrated by FIG. 1, the plurality of sub-pixels 200 includes a plurality of first color sub-pixels 201, a plurality of second color sub-pixels 202 and a plurality of third color sub-pixels 203; the partition structure 140 includes a plurality of first annular partition parts 141, and the first annular partition parts 141 are around at least one of the second color sub-pixels 202. Therefore, the charge generation layer 129 in the light-emitting function layer 120 can be disconnected at the first annular partition part 141, and the first annular partition part 141 can separate the second color sub-pixel 202 from other sub-pixels, thus avoiding crosstalk between the second color sub-pixel and adjacent sub-pixels. It should be noted that although the first annular partition parts shown in FIG. 2 are only arranged around one second color sub-pixel, embodiments of the present disclosure include but are not limited to this case, and each first annular partition part may also surround two or more second color sub-pixels.

For example, as illustrated by FIG. 1, each first annular partition part 141 is around one of the second color sub-pixels 202. Thus, the charge generation layer 129 in the light-emitting function layer 120 can be disconnected at the first annular partition part 141, and the first annular partition part 141 can separate each second color sub-pixel 202 from other sub-pixels.

For example, as illustrated by FIG. 1, in the display substrate 100, the number of the second color sub-pixels 202 is greater than the number of the first color sub-pixels 201; or, the number of the second color sub-pixels 202 is greater than the number of the third color sub-pixels 203; or, the number of second color sub-pixels 202 is greater than the number of the first color sub-pixels 201 and the number of the third color sub-pixels 203. Therefore, just by arranging the first annular partition part 141 on the outer side of the second color sub-pixel 202, most of the adjacent sub-pixels on the display substrate can be separated, so that crosstalk between adjacent sub-pixels can be effectively avoided.

For example, as illustrated by FIG. 1, in the display substrate 100, the number of the second color sub-pixels 202 is roughly twice that of the first color sub-pixels 201 or the third color sub-pixels 203.

In some examples, as illustrated by FIG. 1, the partition structure 140 further includes a plurality of first strip-shaped partition parts 144 and a plurality of second strip-shaped partition parts 145; each first strip-shaped partition part 144 extends along a first direction, and each second strip-shaped partition part 145 extends along a second direction. The first strip-shaped partition part 144 connects two first annular partition parts 141 that are adjacent in the first direction, and the second strip-shaped partition part 145 connects two first annular partition parts 141 that are adjacent in the second direction. A plurality of first strip-shaped partition parts 144 and a plurality of second strip-shaped partition parts 145 connect a plurality of first annular partition parts 141 to form a plurality of first grid structures 161 and a plurality of second grid structures 162 in the regions other than the first annular partition parts 141. One first grid structure 161 is around one first color sub-pixel 201, and one second grid structure 162 is around one third color sub-pixel 203. Therefore, the first strip-shaped partition part can separate the first color sub-pixel and the third color sub-pixel that are adjacent in the second direction, so that the charge generation layer of the light-emitting function layer is disconnected at the position where the first strip-shaped partition part is located, thereby effectively avoiding crosstalk between the first color sub-pixel and the third color sub-pixel adjacent in the second direction; The second strip-shaped partition part can separate the first color sub-pixel and the third color sub-pixel that are adjacent in the first direction, so that the charge generation layer of the light-emitting function layer is disconnected at the position where the second stripe partition is located, thereby effectively avoiding crosstalk between the first color sub-pixel and the third color sub-pixel that are adjacent in the first direction.

For example, the first direction intersects the second direction, for example, the first direction and the second direction are perpendicular to each other.

In some examples, as illustrated by FIG. 1, the display substrate 100 further includes a spacer 170; a plurality of first strip-shaped partition parts 144 and a plurality of second strip-shaped partition parts 145 connect a plurality of first annular partition parts 141 to further form a plurality of third grid structures 163. One third grid structure 163 is around one first color sub-pixel 201 and one third color sub-pixel 203 that are adjacent, and the spacer 170 is located in the third grid structure 163 and between the one first color sub-pixel 201 and the one third color sub-pixel 203 that are adjacent. Therefore, in the case that the space in the first grid structure and the second grid structure is not enough to place the spacer, the third grid structure can provide enough space for the spacer. In addition, because the spacer has a certain height and is located between the first color sub-pixel and the third color sub-pixel in the third grid structure, the spacer can also prevent crosstalk between the first color sub-pixel and the third color sub-pixel in the third grid structure. It should be noted that the spacer is used to support the vapor deposition mask plate for manufacturing the above light-emitting layer.

In some examples, as illustrated by FIG. 1, a plurality of first color sub-pixels 201 and a plurality of third color sub-pixels 203 are alternately arranged along the first direction and the second direction to form a plurality of first pixel rows 310 and a plurality of first pixel columns 320, and a plurality of second color sub-pixels 202 are arranged in an array along the first direction and the second direction to form a plurality of second pixel rows 330 and a plurality of second pixel columns 340. A plurality of first pixel rows 310 and a plurality of second pixel rows 330 are alternately arranged in the second direction and staggered in the first direction, and a plurality of first pixel columns 320 and a plurality of second pixel columns 340 are alternately arranged in the first direction and staggered in the second direction. One partition structure 140 is located between first color sub-pixel 201 and third color sub-pixel 203 that are adjacent, and/or, the partition structure 140 is between adjacent second color sub-pixel 202 and third color sub-pixel 203, and/or between adjacent first color sub-pixel 201 and second color sub-pixel 202.

In some examples, the light-emitting efficiency of the third color sub-pixel is less than that of the second color sub-pixel.

For example, the first color sub-pixel 201 is configured to emit red light, the second color sub-pixel 202 is configured to emit green light, and the third color sub-pixel 203 is configured to emit blue light. Of course, embodiments of the present disclosure include but are not limited to this.

In some examples, as illustrated by FIG. 1, the shape of the orthographic projection of the effective light-emitting region of the first color sub-pixel 201 on the base substrate 110 includes a rounded rectangle; the shape of the orthographic projection of the effective light-emitting region of the second color sub-pixel 202 on the base substrate 110 includes a rounded rectangle; the shape of the orthographic projection of the effective light-emitting region of the third color sub-pixel 203 on the base substrate 110 includes a rounded rectangle. It should be noted that the above-mentioned effective light-emitting region may be roughly the region defined by the pixel opening corresponding to the sub-pixel.

In some examples, as illustrated by FIG. 1, the shape of the orthographic projection of the effective light-emitting region of the third color sub-pixel 203 on the base substrate 110 includes a plurality of rounded corners, the plurality of rounded corners include a first rounded corner 2031, and the arc radius of the first rounded corner 2031 is larger than that of other rounded corners. In this case, because the arc radius of the first rounded corner 2031 is large, the space occupied by the first rounded corner 2031 is small, so the spacer 170 can be arranged close to the first rounded corner 2031, so that the area on the display substrate can be fully utilized and the pixels per inch can be improved. In this case, the first rounded corner 2031 is the rounded corner with the smallest distance from the first color sub-pixel 201 among the rounded corners of the third color sub-pixel 203.

In some examples, as illustrated by FIG. 1, the orthographic projection of the spacer 170 on the base substrate 110 is located on the connection line between the midpoint of the first rounded corner 2031 and the brightness center of the first color sub-pixel 201.

In some examples, as illustrated by FIG. 1, the shape of the orthographic projection of the effective light-emitting region of the third color sub-pixel 203 on the base substrate 110 includes a plurality of rounded corners, and the plurality of rounded corners include a first rounded corner 2031 and a second rounded corner 2032, and the arc radius of the first rounded corner 2031 is larger than that of the second rounded corner 2031; in addition, the shape of the orthographic projection of the effective light-emitting region of the third color sub-pixel 203 on the base substrate 110 is symmetrical about the connection line that connects the first rounded corner 2031 and the second rounded corner 2032.

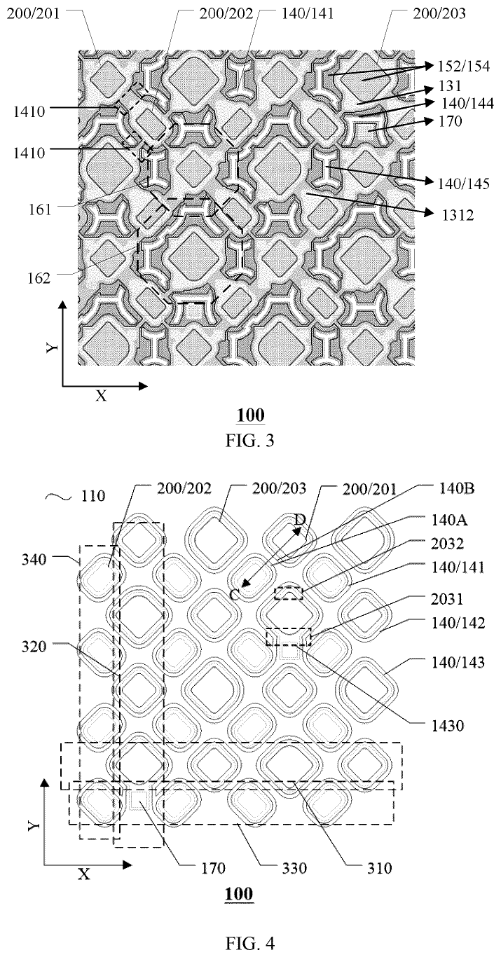

FIG. 3 is a schematic planar view of another display substrate provided by an embodiment of the present disclosure. As illustrated by FIG. 3, the first annular partition part 141 includes at least one notch 1410. In the case that the first annular partition part is arranged outside the second color sub-pixel, not only the charge generation layer of the light-emitting function layer will break at the first annular partition part, but also the second electrode above the light-emitting function layer may break at the position where the first annular partition part is located, so that the cathode signal cannot be transmitted to the second color sub-pixel. Therefore, by arranging the at least one notch in the first annular partition part, the display substrate can prevent the first annular partition part from completely isolating the second color sub-pixels, thereby avoiding the phenomenon that the cathode signal cannot be transmitted.

In some examples, as illustrated by FIG. 3, one second color sub-pixel 202 is surrounded by two first color sub-pixels 201 and two third color sub-pixels 203; in this case, the first annular partition part 141 includes four notches 1410 which are respectively located between the one second color sub-pixel 202 and the four sub-pixels 200 adjacent to the one second color sub-pixel 202. Therefore, by providing the notches, the second electrode or cathode between the one second color sub-pixel and the surrounding four sub-pixels cannot be disconnected, thus facilitating the transmission of cathode signals. It should be noted that although the first annular partition part is provided with the above notches, the size of each notch is relatively small, which can greatly increase the resistance of the conductive sub-layer (for example, the charge generation layer) at the position of the notch, thus effectively blocking the passage of current, and thus effectively avoiding crosstalk between adjacent sub-pixels. Moreover, because the conductivity of the second electrode is greater than that of the conductive sub-layer, and a plurality of sub-pixels share the second electrode and there are a plurality of conductive channels, even if the size of the notch is relatively small, it will not hinder the transmission of the cathode signals.

In some examples, as illustrated by FIG. 3, the first electrode 131 of the second color sub-pixel 202 includes an electrode connection part 1312, and the orthographic projection of the electrode connection part 1312 on the base substrate 110 at least partially overlaps with the orthographic projection of the notch 1410 of the first annular partition part 141 on the base substrate 110. Therefore, the position where the notch of the first annular partition part is located in the display substrate can be used to arrange the electrode connection part, thereby making the sub-pixel layout more compact and improving the pixels per inch. It should be noted that the brightness center of each sub-pixel may be the geometric center of the effective light-emitting region of the sub-pixel. Of course, the embodiments of the present disclosure include but are not limited to this case, and the brightness center of each sub-pixel may also be the position where the maximum value of the light-emitting brightness of the sub-pixel is located.

In some examples, as illustrated by FIG. 3, the first electrode 131 of the first color sub-pixel 201 also includes an electrode connection part 1312, and the first electrode 131 of the third color sub-pixel 203 also includes an electrode connection part 1312; both the orthographic projection of the electrode connection part 1312 of the first color sub-pixel 201 and the electrode connection part 1312 of the third color sub-pixel 203 on the base substrate 110 also at least partially overlap with the orthographic projection of the notch 1410 of the first annular partition part 141 on the base substrate 110. Therefore, the position where the notch of the first annular partition part is located in the display substrate can further be utilized to arrange the electrode connection part of the first color sub-pixel and the electrode connection part of the third color sub-pixel, thereby making the sub-pixel layout more compact and improving the pixels per inch.

In some examples, as illustrated by FIG. 3, the partition structure 140 further includes a plurality of first strip-shaped partition parts 144 and a plurality of second strip-shaped partition parts 145; each first strip-shaped partition part 144 extends in the first direction, and each second strip-shaped partition part 145 extends in the second direction. One first strip-shaped partition part 144 connects two first annular partition parts 141 adjacent in the first direction, and one second strip-shaped partition part 145 connects two first annular partition parts 141 adjacent in the second direction. A plurality of first strip-shaped partition parts 144 and a plurality of second strip-shaped partition parts 145 connect a plurality of first annular partition parts 141 to form a plurality of first grid structures 161 and a plurality of second grid structures 162 in the regions other than the first annular partition parts 141. One first grid structure 161 is around one first color sub-pixel 201, and one second grid structure 162 is around one third color sub-pixel 203. Therefore, the first strip-shaped partition part can separate the first color sub-pixel and the third color sub-pixel adjacent in the second direction, so that the charge generation layer of the light-emitting function layer is disconnected at the position where the first stripe partition is located, thereby effectively avoiding crosstalk between the first color sub-pixel and the third color sub-pixel adjacent in the second direction; the second stripe partition can separate the first color sub-pixel and the third color sub-pixel adjacent in the first direction, so that the charge generation layer of the light-emitting function layer is disconnected at the position where the second stripe partition is located, thereby effectively avoiding crosstalk between the first color sub-pixel and the third color sub-pixel adjacent in the first direction.

For example, the first direction intersects the second direction, for example, the first direction and the second direction are perpendicular to each other.

In some examples, as illustrated by FIG. 3, the notch 1410 of the first annular partition part 141 also serves as a notch of the first grid structure 161 and a notch of the second grid structure 162. Therefore, the second electrode of the first color sub-pixel 201 located in the first grid structure 161 and the second electrode of the third color sub-pixel 203 located in the second grid structure 162 will not be completely disconnected, thus facilitating the transmission of cathode signals.

In some examples, as illustrated by FIG. 3, the display substrate 100 further includes a spacer 170; the spacer 170 is located within the first grid structure 161 and between the first color sub-pixel 201 and the third color sub-pixel 203. In the case that the space in the first grid structure is enough to place the spacer, the spacer can be directly placed in the first grid structure. It should be noted that the embodiment of the present disclosure includes but is not limited to this case, and the spacer may also be located within the second grid structure; in addition, the above-mentioned “within the first/second grid structure” refers to within the space surrounded by the grid structure, not inside the grid structure itself.

FIG. 4 is a schematic planar view of another display substrate provided by an embodiment of the present disclosure. As illustrated by FIG. 4, the plurality of sub-pixels 200 includes a plurality of first color sub-pixels 201, a plurality of second color sub-pixels 202 and a plurality of third color sub-pixels 203. The partition structure 140 includes a plurality of first annular partition parts 141, a plurality of second annular partition parts 142 and a plurality of third annular partition parts 143. Each first annular partition part 141 is arranged around one of the plurality of second color sub-pixels 202. Each second annular partition part 142 is arranged around one of the plurality of first color sub-pixels 201; each third annular partition part 143 is arranged around one of the plurality of third color sub-pixels 203.

In the display substrate shown in FIG. 4, the charge generation layer 129 of the light-emitting function layer 120 can be disconnected at the first annular partition part 141, be disconnected at the second annular partition part 142 and be disconnected at the third annular partition part 143, and the first annular partition part 141 can separate the second color sub-pixel 202 from other sub-pixels, so that crosstalk between the second color sub-pixel and adjacent sub-pixels can be avoided; the second annular partition part 142 can separate the first color sub-pixel 201 from other sub-pixels, so that crosstalk between the first color sub-pixel and adjacent sub-pixels can be avoided; the third annular partition part 143 can separate the third color sub-pixel 203 from other sub-pixels, so that crosstalk between the third color sub-pixel and adjacent sub-pixels can be avoided.

FIG. 5 is a schematic cross-sectional view of a display substrate taken along the direction CD in FIG. 4 provided by an embodiment of the present disclosure. As illustrated by FIG. 5, the partition structure 140 between the first color sub-pixel 201 and the second color sub-pixel 202 includes a part of the first annular partition part 141 and a part of the second annular partition part 142. In this case, the part of the first annular partition part 141 can be used as the first sub-partition structure 140A of the partition structure 140, and the part of the second annular partition part 142 can be used as the second sub-partition structure 140B of the partition structure 140. The first sub-partition structure 140A and second sub-partition structure 140B are sequentially arranged in the arrangement direction of adjacent sub-pixels 200. In the case that the charge generation layer of the light-emitting function layer is not disconnected or not completely disconnected at the position where the first sub-partition structure is located, the charge generation layer of the light-emitting function layer can be disconnected at the position where the second sub-partition structure is located. Therefore, by sequentially arranging the first sub-partition structure and the second sub-partition structure in the arrangement direction of adjacent sub-pixels, the display substrate can better disconnect the charge generation layer of the light-emitting function layer at the position where the partition structure is located, thereby further avoiding the crosstalk between adjacent sub-pixels caused by the charge generation layer with higher conductivity. Of course, the embodiments of the present disclosure include but are not limited to this case, and only one sub-partition structure may be provided in the case that the space distance between adjacent sub-pixels is small.

In some examples, as illustrated by FIG. 4, both the first annular partition part 141 and the second annular partition part 142 are complete closed annular structures, and do not include a notch; the third annular partition part 143 includes a notch 1430, and two ends of the third annular partition part 143 at the notch 1430 are respectively connected with two first annular partition parts 141 adjacent in the first direction or the second direction. Therefore, in the case that the pixels per inch of the display substrate is relative high and the partition structure includes the above-mentioned first annular partition part, second annular partition part and third annular partition part, the space between adjacent annular partition parts may not be enough to provide the spacer; in this case, by providing the notch in the third annular partition part, the display substrate can be provided with a spacer at the position where the notch is located; moreover, because the two ends of the third annular partition part at the notch are respectively connected with two first annular partition parts adjacent in the first direction or the second direction, the display substrate can better avoid crosstalk between adjacent sub-pixels.

It should be noted that although the third annular partition part of the display substrate shown in FIG. 4 is provided with a notch, the embodiment of the present disclosure includes but is not limited to this case, and the third annular partition part may also be a complete closed annular structure. In addition, in the case that all the first annular partition part, the second annular partition part or the third annular partition part are complete closed annular structures, the conductive sub-layer of the light-emitting function layer can be disconnected at the position of the annular partition part structure by controlling the height, depth or other parameters of the annular partition part structure, so that the second electrode is not disconnected at the position of the annular partition part structure.

In some examples, as illustrated by FIG. 4, the shape of the orthographic projection of the effective light-emitting region of the first color sub-pixel 201 on the base substrate 110 includes a rounded rectangle; the shape of the orthographic projection of the effective light-emitting region of the second color sub-pixel 202 on the base substrate 110 includes a rounded rectangle; the shape of the orthographic projection of the effective light-emitting region of the third color sub-pixel 203 on the base substrate 110 includes a rounded rectangle.

In some examples, as illustrated by FIG. 4, the shape of the orthographic projection of the effective light-emitting region of the third color sub-pixel 203 on the base substrate 110 includes a plurality of rounded corners, and the plurality of rounded corners include a first rounded corner 2031, and the arc radius of the first rounded corner 2031 is larger than that of other rounded corners. In this case, because the arc radius of the first rounded corner 2031 is relatively large, the space occupied by the first rounded corner 2031 is relatively small. Therefore, the notch 1430 of the third annular partition part 143 can be arranged close to the first rounded corner 2031, and the spacer 170 is also correspondingly arranged close to the first rounded corner 2031, so that the area on the display substrate can be fully utilized and the pixels per inch can be improved. In this case, the first rounded corner 2031 is the rounded corner with the smallest distance from the first color sub-pixel 201 among the plurality of rounded corners of the third color sub-pixel 203.

In some examples, as illustrated by FIG. 4, the orthographic projection of the spacer 170 on the base substrate 110 is on the connection line between the midpoint of the first rounded corner 2031 and the brightness center of the first color sub-pixel 201.

In some examples, as illustrated by FIG. 4, the shape of the orthographic projection of the effective light-emitting region of the third color sub-pixel 203 on the base substrate 110 includes a plurality of rounded corners, and the plurality of rounded corners include a first rounded corner 2031 and a second rounded corner 2032, and the arc radius of the first rounded corner 2031 is larger than that of the second rounded corner 2031; and, the shape of the orthographic projection of the effective light-emitting region of the third color sub-pixel 203 on the base substrate 110 is symmetrical about the connection line that connects the first rounded corner 2031 and the second rounded corner 2032.

In some examples, as illustrated by FIG. 4, the shape of the orthographic projection of the effective light-emitting region of the first color sub-pixel 201 on the base substrate 110 also includes a plurality of rounded corners, and the arc radii of these rounded corners are equal.

In some examples, as illustrated by FIG. 4, the shape of the orthographic projection of the effective light-emitting region of the second color sub-pixel 202 on the base substrate 110 also includes a plurality of rounded corners, and the arc radii of these rounded corners are equal.

In some examples, as illustrated by FIG. 4, the area of the orthographic projection of the effective light-emitting region of the third color sub-pixel 203 on the base substrate 110 is larger than that of the effective light-emitting region of the first color sub-pixel 201 on the base substrate 110; the area of the orthographic projection of the effective light-emitting region of the first color sub-pixel 201 on the base substrate 110 is larger than that of the effective light-emitting region of the second color sub-pixel 202 on the base substrate 110. Of course, the embodiments of the present disclosure include but are not limited to this case, and the area of the effective light-emitting region of each sub-pixel can be design according to actual needs.

In some examples, as illustrated by FIG. 4, a plurality of first color sub-pixels 201 and a plurality of third color sub-pixels 203 are alternately arranged along both the first direction and the second direction to form a plurality of first pixel rows 310 and a plurality of first pixel columns 320, and a plurality of second color sub-pixels 202 are arranged in an array along both the first direction and the second direction to form a plurality of second pixel rows 330 and a plurality of second pixel columns 340. A plurality of first pixel rows 310 and a plurality of second pixel rows 330 are alternately arranged in the second direction and staggered in the first direction, and a plurality of first pixel columns 320 and a plurality of second pixel columns 340 are alternately arranged in the first direction and staggered in the second direction. The partition structure 140 is located between the first color sub-pixel 201 and the third color sub-pixel 203 that are adjacent, and/or, the partition structure 140 is located between adjacent second color sub-pixel 202 and third color sub-pixel 203, and/or, the partition structure 140 is located between adjacent first color sub-pixel 201 and second color sub-pixel 202.

In some examples, the light-emitting efficiency of the third color sub-pixel is less than that of the second color sub-pixel.

For example, the first color sub-pixel 201 is configured to emit red light, the second color sub-pixel 202 is configured to emit green light, and the third color sub-pixel 203 is configured to emit blue light. Of course, embodiments of the present disclosure include but are not limited to this case.

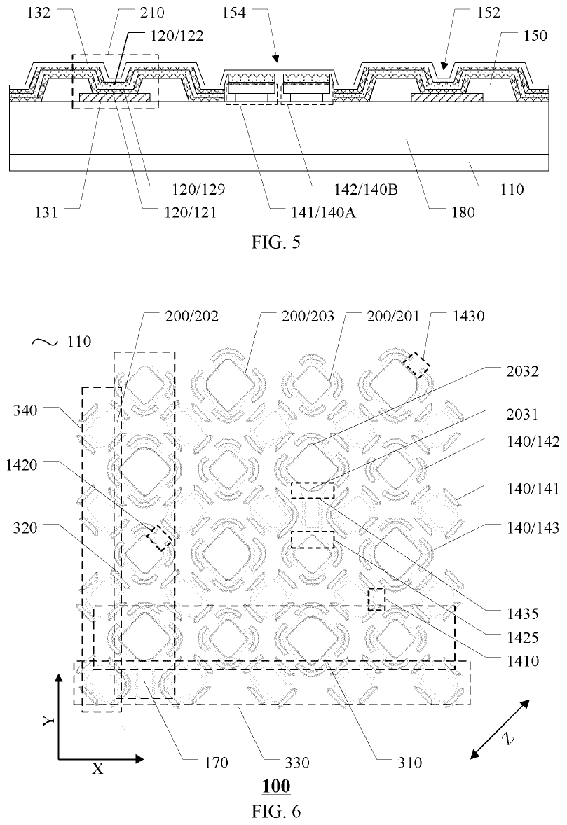

FIG. 6 is a schematic planar view of further another display substrate provided by an embodiment of the present disclosure. As illustrated by FIG. 6, a plurality of sub-pixels 200 includes a plurality of first color sub-pixels 201, a plurality of second color sub-pixels 202 and a plurality of third color sub-pixels 203. A plurality of first color sub-pixels 201 and a plurality of third color sub-pixels 203 are alternately arranged along both the first direction and the second direction to form a plurality of first pixel rows 310 and a plurality of first pixel columns 320, and a plurality of second color sub-pixels 202 are arranged in an array along both the first direction and the second direction to form a plurality of second pixel rows 330 and a plurality of second pixel columns 340. A plurality of first pixel rows 310 and a plurality of second pixel rows 330 are alternately arranged in the second direction and staggered in the first direction, and a plurality of first pixel columns 320 and a plurality of second pixel columns 340 are alternately arranged in the first direction and staggered in the second direction. The partition structure 140 includes a plurality of first annular partition parts 141, a plurality of second annular partition parts 142 and a plurality of third annular partition parts 143. Each first annular partition part 141 is arranged around one of the plurality of second color sub-pixels 202. Each second annular partition part 142 is arranged around one of the plurality of first color sub-pixels 201; each third annular partition part 143 is arranged around one of the plurality of third color sub-pixels 203.

In the display substrate shown in FIG. 6, the charge generation layer 129 of the light-emitting function layer 120 can be disconnected at the first annular partition part 141, can be disconnected at the second annular partition part 142 and can be disconnected at the third annular partition part 143, and the first annular partition part 141 can separate the second color sub-pixel 202 from other sub-pixels, thus avoiding crosstalk between the second color sub-pixel and adjacent sub-pixels; the second annular partition part 142 can separate the first color sub-pixel 201 from other sub-pixels, thereby avoiding crosstalk between the first color sub-pixel and adjacent sub-pixels; the third annular partition part 143 can separate the third color sub-pixel 203 from other sub-pixels, so that crosstalk between the third color sub-pixel and adjacent sub-pixels can be avoided.

In some examples, as illustrated by FIG. 6, the first annular partition part 141 includes at least one notch 1410, the second annular partition part 142 includes at least one notch 1420, and the third annular partition part 143 includes at least one notch 1430. In the case that it is possible for the second electrode on the light-emitting function layer to be broken at the positions where the first annular partition part, the second annular partition part and the third annular partition part are located, by providing the at least one notch on the first annular partition part, the at least one notch on the second annular partition part and the at least one notch on the third annular partition part, the display substrate can prevent the first annular partition part, the second annular partition part and the third annular partition part from completely isolating the respective sub-pixels, thus avoiding the phenomenon that cathode signals cannot be transmitted normally.

In some examples, as illustrated by FIG. 6, the notches of any two adjacent annular partition parts in the first annular partition part 141, the second annular partition part 142 and the third annular partition part 143 are arranged in a staggered manner to ensure that at least one partition structure exist between two adjacent sub-pixels, so that crosstalk between the two adjacent sub-pixels can be effectively avoided.

In some examples, as illustrated by FIG. 6, between the first color sub-pixel 201 and the second color sub-pixel 202 which are adjacent to each other, the shortest path for charges to propagate from the first color sub-pixel 201 to the second color sub-pixel 202 is the position where the connection line connecting the center of the effective light-emitting region of the first color sub-pixel 201 and the center of the effective light-emitting region of the second color sub-pixel 202 is located. In order to effectively avoid crosstalk between the first color sub-pixel 201 and the second color sub-pixel 202, it is necessary to arrange a partition structure on the connection line connecting the center of the effective light-emitting region of the first color sub-pixel 201 and the center of the effective light-emitting region of the second color sub-pixel 202. Therefore, the notch 1410 of the first annular partition part 141 outside the second color sub-pixel 202 and the notch 1420 of the second annular partition part 142 outside the first color sub-pixel 201 cannot be both located on the connection line connecting the center of the effective light-emitting region of the first color sub-pixel 201 and the center of the effective light-emitting region of the second color sub-pixel 202. It should be noted that in the case that the charge cannot propagate from the first color sub-pixel 201 to the second color sub-pixel 202 along the shortest path, and at least the first annular partition part 141 or the second annular partition part 142 needs to be bypassed by the charge, the resistance of the charge generation layer of the light-emitting function layer is large due to the long propagation path of the charge, and the crosstalk between adjacent sub-pixels can also be effectively avoided.

For example, as illustrated by FIG. 6, between the first color sub-pixel 201 and the second color sub-pixel 202 which are adjacent to each other, the notch 1420 of the second annular partition part 142 is spaced from the connection line connecting the center of the effective light-emitting region of the first color sub-pixel 201 and the center of the effective light-emitting region of the second color sub-pixel 202. That is, the notch 1420 of the second annular partition part 142 is not arranged on the connection line connecting the center of the effective light-emitting region of the first color sub-pixel 201 and the center of the effective light-emitting region of the second color sub-pixel 202.

In some examples, as illustrated by FIG. 6, similarly, in order to effectively avoid crosstalk between the third color sub-pixel 203 and the second color sub-pixel 202, it is necessary to arrange a partition structure on the connection line connecting the center of the effective light-emitting region of the third color sub-pixel 203 and the center of the effective light-emitting region of the second color sub-pixel 202. Therefore, the notch 1410 of the first annular partition part 141 outside the third color sub-pixel 202 and the notch 1430 of the third annular partition part 143 outside the third color sub-pixel 203 cannot be both located on connection line connecting the center of the effective light-emitting region of the third color sub-pixel 203 and the center of the effective light-emitting region of the second color sub-pixel 202.

For example, as illustrated by FIG. 6, between the third color sub-pixel 203 and the second color sub-pixel 202 which are adjacent to each other, the notch 1420 of the second annular partition part 142 is spaced from the connection line connecting the center of the effective light-emitting region of the third color sub-pixel 203 and the center of the effective light-emitting region of the second color sub-pixel 202. That is, the notch 1420 of the second annular partition part 142 is not arranged on the connection line connecting the center of the effective light-emitting region of the third color sub-pixel 203 and the center of the effective light-emitting region of the second color sub-pixel 202.

In some examples, as illustrated by FIG. 6, among the first annular partition part 141 and the second annular partition part 142 adjacent to each other in the third direction Z, one notch 1410, that is closest to the second annular partition part 142, of at least one notch 1410 of the first annular partition part 141, and one notch 1420, that is closest to the first annular partition part 141, of at least one notch 1420 of the second annular partition part 142, are staggered in the third direction.

It should be noted that the third direction intersects with the first direction and the second direction respectively, and is in the same plane as both the first direction and the second direction; for example, the third direction may be the extension direction of the connection line connecting the centers of the effective light-emitting region of the first color sub-pixel and the effective light-emitting region of the second color sub-pixel that are adjacent.

In some examples, as illustrated by FIG. 6, among the first annular partition part 141 and the third annular partition part 143 which are adjacent to each other in the third direction Z, one notch 1410, that is closest to the third annular partition part 143, of at least one notch 1410 of the first annular partition part 141, and one notch 1430, that is closest to the first annular partition part 141, of at least one notch 1430 of the third annular partition part 143 are also staggered in the third direction.

In some examples, as illustrated by FIG. 6, the shape of the orthographic projection of the effective light-emitting region of the second color sub-pixel 202 on the base substrate 110 includes a rounded rectangle which includes four rounded corners; in this case, the first annular partition part 141 includes four notches 1410, and these four notches 1410 are respectively arranged corresponding to the four rounded corners of the effective light-emitting region of the second color sub-pixel 202. The shape of the orthographic projection of the effective light-emitting region of the first color sub-pixel 201 on the base substrate includes a rounded rectangle which includes four edges; in this case, the second annular partition part 142 includes four notches 1420, and these four notches 1420 are respectively arranged corresponding to the four edges of the effective light-emitting region of the first color sub-pixel 201. The shape of the orthographic projection of the effective light-emitting region of the first color sub-pixel 203 on the base substrate includes a rounded rectangle which includes four edges; in this case, the third annular partition part 143 includes four notches 1430, and these four notches 1430 are respectively arranged corresponding to the four edges of the effective light-emitting region of the third color sub-pixel 203. With this arrangement, the display substrate can ensure that the notches of the annular partition parts outside adjacent two sub-pixels are staggered, thereby ensuring that at least a partition structure exists between the adjacent two sub-pixels.

In some examples, as illustrated by FIG. 6, the display substrate 100 further includes a spacer 170; in this case, the annular partition part close to the spacer 170 is different from the annular partition part at other positions. The spacer 170 is surrounded by one first color sub-pixel 201, two second color sub-pixels 202 and one third color sub-pixel 203; and the one first color sub-pixel 201 and the one third color sub-pixel 203 are respectively arranged on two sides of the spacer 170 in the second direction Y; the two second color sub-pixels 202 are respectively arranged on two sides of the spacer 170 in the first direction X.

In some examples, as illustrated by FIG. 6, the second annular partition part 142 outside the first color sub-pixel 201 includes the spacer notch 1425 at the position of the second annular partition part 142 close to the spacer 170, and the third annular partition part 143 outside the third color sub-pixel 203 includes the spacer notch 1435 at the position of the third annular partition part 143 close to the spacer 170. Therefore, the display substrate can provide enough space for placing the spacers. Moreover, because the spacer itself has a certain partition function, the spacer notch will not cause crosstalk between the first color sub-pixel and the third color sub-pixel.

In some examples, as illustrated by FIG. 6, because the second annular partition part 142 is provided with the above-mentioned spacer notch 1425, the third partition 143 is provided with the above-mentioned spacer notch 1435, and positions, of the two first annular partition parts 141 located on two sides of the spacer 170, close to the spacer 170 are not provided with notches, so that crosstalk between adjacent sub-pixels can be effectively avoided.

In some examples, as illustrated by FIG. 6, the size of the spacer 170 in the second direction Y is larger than the size of the spacer 170 in the first direction X.

For example, as illustrated by FIG. 6, the shape of the orthographic projection of the effective light-emitting region of the third color sub-pixel 203 on the base substrate 110 includes a plurality of rounded corners, the plurality of rounded corners include a first rounded corner 2031, and the arc radius of the first rounded corner 2031 is larger than that of other rounded corners. In this case, because the arc radius of the first rounded corner 2031 is relative large, the space occupied by the first rounded corner 2031 is small, so the spacer notch 1435 can be arranged close to the first rounded corner 2031, so that the area on the display substrate can be fully utilized and the pixels per inch can be improved. In this case, the first rounded corner 2031 is the rounded corner with the smallest distance from the first colored sub-pixel 201 among the plurality of rounded corners of the third colored sub-pixel 203.

In some examples, as illustrated by FIG. 6, the shape of the orthographic projection of the effective light-emitting region of the third color sub-pixel 203 on the base substrate 110 includes a plurality of rounded corners, and the plurality of rounded corners include a first rounded corner 2031 and a second rounded corner 2032, and the arc radius of the first rounded corner 2031 is larger than that of the second rounded corner 2031; and, the shape of the orthographic projection of the effective light-emitting region of the third color sub-pixel 203 on the base substrate 110 is symmetrical about the connection line which connects the first rounded corner 2031 and the second rounded corner 2032.

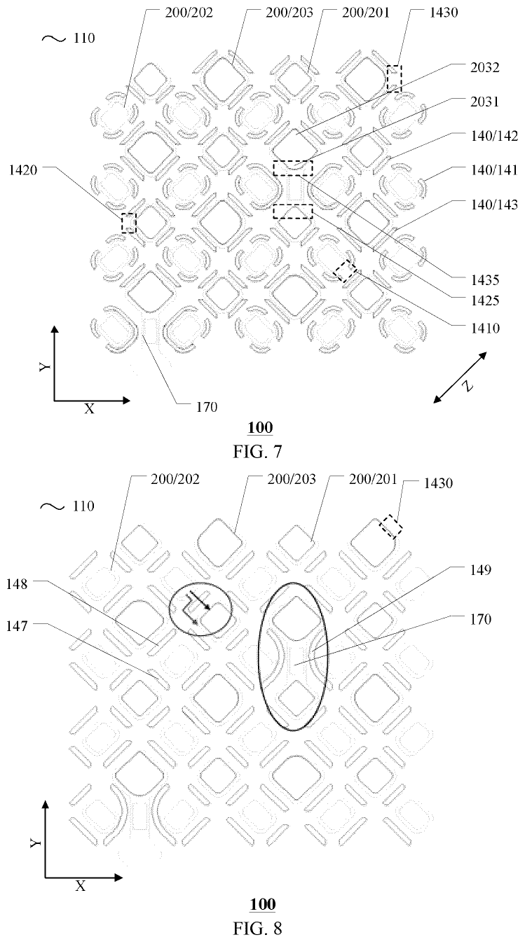

FIG. 7 is a schematic planar view of further another display substrate provided by an embodiment of the present disclosure. As illustrated by FIG. 7, the display substrate shown in FIG. 7 and the display substrate shown in FIG. 6 adopt the same pixel arrangement. In this case, the partition structure 140 includes a plurality of first annular partition parts 141, a plurality of second annular partition parts 142 and a plurality of third annular partition parts 143. Each first annular partition part 141 is around one of the second color sub-pixels 202; each second annular partition part 142 is around one first color sub-pixel 201; and each third annular partition part 143 is around one third color sub-pixel 203, so that crosstalk between the second color sub-pixel and adjacent sub-pixels can be avoided.

In some examples, as illustrated by FIG. 7, the first annular partition part 141 includes at least one notch 1410, the second annular partition part 142 includes at least one notch 1420, and the third annular partition part 143 includes at least one notch 1430. Moreover, the notches of any two adjacent annular partition parts selected from the group consisting of the first annular partition part 141, the second annular partition part 142 and the third annular partition part 143 are arranged in a staggered manner to ensure that at least a partition structure exists between two adjacent sub-pixels, so that crosstalk between adjacent sub-pixels can be effectively avoided.

In some examples, as illustrated by FIG. 7, between the first color sub-pixel 201 and the second color sub-pixel 202 which are arranged adjacent to each other, the notch 1410 of the first annular partition part 141 is spaced apart from the connection line of the center of the effective light-emitting region of the first color sub-pixel 201 and the center of the effective light-emitting region of the second color sub-pixel 202. That is, the notch 1410 of the first annular partition part 141 is not on the connection line of the center of the effective light-emitting region of the first color sub-pixel 201 and the center of the effective light-emitting region of the second color sub-pixel 202.

In some examples, as illustrated by FIG. 7, between the third color sub-pixel 203 and the second color sub-pixel 202 which are arranged adjacent to each other, the notch 1430 of the third annular partition part 143 is spaced apart from the connection line of the center of the effective light-emitting region of the third color sub-pixel 203 and the center of the effective light-emitting region of the second color sub-pixel 202. That is, the notch 1430 of the third annular partition part 143 is not on the connection line between the center of the effective light-emitting region of the third color sub-pixel 203 and the center of the effective light-emitting region of the second color sub-pixel 202.

In some examples, as illustrated by FIG. 7, the shape of the orthographic projection of the effective light-emitting region of the second color sub-pixel 202 on the base substrate 110 includes a rounded rectangle which includes four edges; in this case, the first annular partition part 141 includes four notches 1410, and these four notches 1410 are respectively arranged corresponding to the four edges of the effective light-emitting region of the second color sub-pixel 202. The shape of the orthographic projection of the effective light-emitting region of the first color sub-pixel 201 on the base substrate includes a rounded rectangle which includes four rounded corners; in this case, the second annular partition part 142 includes four notches 1420, and these four notches 1420 are respectively arranged corresponding to the four rounded corners of the effective light-emitting region of the first color sub-pixel 201. The shape of the orthographic projection of the effective light-emitting region of the first color sub-pixel 203 on the base substrate includes a rounded rectangle which includes four rounded corners; in this case, the third annular partition part 143 includes four notches 1430, and these four notches 1430 are respectively arranged corresponding to the four rounded corners of the effective light-emitting region of the third color sub-pixel 203. With this arrangement, the display substrate can ensure that the gaps of the annular partition parts outside the adjacent two sub-pixels are staggered, thereby ensuring that at least a partition structure exists between the adjacent two sub-pixels.

In some examples, as illustrated by FIG. 7, the display substrate 100 further includes a spacer 170; in this case, the annular partition part close to the spacer 170 is different from the annular partition part at other positions. The spacer 170 is surrounded by one first color sub-pixel 201, two second color sub-pixels 202 and one third color sub-pixel 203. The first color sub-pixel 201 and the third color sub-pixel 203 are respectively arranged on two sides of the spacer 170 in the second direction Y; two second color sub-pixels 202 are respectively arranged on two sides of the spacer 170 in the first direction X.

In some examples, as illustrated by FIG. 7, the second annular partition part 142 outside the first color sub-pixel 201 includes a spacer notch 1425 at the position of the second annular partition part 142 close to the spacer 170, and the position where the spacer notch 1425 is located is not provided with a partition structure; the spacer notch 1425 extends from the space between one first color sub-pixel 201 and one second color sub-pixel 202, through the space between the one first color sub-pixel 201 and the spacer 170, to the space between the one first color sub-pixel 201 and another second color sub-pixel 202. That is, the second annular partition part 142 outside the first color sub-pixel 201 close to the spacer 170 includes only two strip-shaped partition parts. The third annular partition part 143 outside the third color sub-pixel 203 includes a spacer notch 1435 at the position of the third annular partition part 143 close to the spacer 170, and the position where the spacer notch 1435 is located is not provided with a partition structure; the spacer notch 1435 extends from the space between one third color sub-pixel 203 and one second color sub-pixel 202, through the space between the one third color sub-pixel 203 and the spacer 170, to the space between the one third color sub-pixel 203 and another second color sub-pixel 202. That is, the third annular partition part 143 outside the third color sub-pixel 203 close to the spacer includes only two strip-shaped partition parts. Therefore, the display substrate can provide enough space for placing the spacers. Moreover, because the spacer itself has a certain partition function, the spacer notch will not cause crosstalk between the first color sub-pixel and the third color sub-pixel.

In some examples, as illustrated by FIG. 7, because the second annular partition part 142 is provided with the above-mentioned spacer notch 1425, the third partition 143 is provided with the above-mentioned spacer notch 1435; and the positions, close to the spacer 170, of the two first annular partition parts 141 located on the two sides of the spacer 170 are both not provided with notches, so that crosstalk between adjacent sub-pixels can be effectively avoided.

In some examples, as illustrated by FIG. 7, the size of the spacer 170 in the second direction Y is larger than the size of the spacer 170 in the first direction X.

FIG. 8 is a schematic planar view of further another display substrate provided by an embodiment of the present disclosure. As illustrated by FIG. 8, the plurality of sub-pixels 200 includes a plurality of first color sub-pixels 201, a plurality of second color sub-pixels 202 and a plurality of third color sub-pixels 203; the partition structure 140 includes a third strip-shaped partition part 147 and a fourth strip partition 148. The third strip-shaped partition part 147 is located between the first color sub-pixel 201 and second color sub-pixel 202 that are adjacent. The fourth strip-shaped partition part 148 is located between the third color sub-pixel 203 and the second color sub-pixel 202 that are adjacent.

In some examples, as illustrated by FIG. 8, the extending direction of the third strip-shaped partition part 147 is perpendicular to the connection line connecting the centers of the effective light-emitting region of the first color sub-pixel 201 and the effective light-emitting region of the second color sub-pixel 202 that are adjacent; the extending direction of the fourth strip-shaped partition part 148 is perpendicular to the connection line connecting the centers of the effective light-emitting region of the third color sub-pixel 203 and the effective light-emitting region of the second color sub-pixel 202 that are adjacent.

In some examples, as illustrated by FIG. 8, the orthographic projection of the effective light-emitting region of the first color sub-pixel 201 on the base substrate 110 is a rounded rectangle, and the size (i.e. length) of the third strip-shaped partition part 147 in its extension direction is 0.8˜1 times the length of an edge of the effective light-emitting region of the first color sub-pixel 201.

In some examples, as illustrated by FIG. 8, the orthographic projection of the effective light-emitting region of the third color sub-pixel 201 on the base substrate 110 is a rounded rectangle, and the size (i.e. length) of the fourth strip partition 148 in its extension direction is 0.8˜1 times the length of an edge of the effective light-emitting region of the third color sub-pixel 203.

In some examples, as illustrated by FIG. 8, the display substrate 100 further includes a spacer 170; in this case, the partition structure close to the spacer 170 is different from that at other positions. The spacer 170 is surrounded by one first color sub-pixel 201, two second color sub-pixels 202 and one third color sub-pixel 203; the one first color sub-pixel 201 and the one third color sub-pixel 203 are respectively arranged on two sides of the spacer 170 in the second direction Y; the two second color sub-pixels 202 are respectively arranged on two sides of the spacer 170 in the first direction X.

In some examples, as illustrated by FIG. 8, the partition structure 140 includes an arc line-shaped partition part 149 located between the second color sub-pixel 202 and the spacer 170; and the arc line-shaped partition part 149 extends from the space between the second color sub-pixel 202 and the third color sub-pixel 203 to the space between the second color sub-pixel 202 and the first color sub-pixel 201. That is, one end of the arc line-shaped partition part 149 is located between the second color sub-pixel 202 and the third color sub-pixel 203, and can play the role of the fourth strip-shaped partition part 148. The other end of the arc line-shaped partition part 149 is located between the second color sub-pixel 202 and the first color sub-pixel 201, and can play the role of the third strip-shaped partition part 147. The middle part of the arc line-shaped partition part 149 is located between the second color sub-pixel 202 and the spacer 170.

FIG. 9 is a schematic planar view of further another display substrate provided by an embodiment of the present disclosure. As illustrated by FIG. 9, the plurality of sub-pixels 200 includes a plurality of first color sub-pixels 201, a plurality of second color sub-pixels 202 and a plurality of third color sub-pixels 203; the partition structure 140 includes a plurality of first annular partition parts 141, a plurality of second annular partition parts 142 and a plurality of third annular partition parts 143. Each first annular partition part 141 is around two adjacent second color sub-pixels 202; each second annular partition part 142 is around one first color sub-pixel 201; and each third annular partition part 143 is around one third color sub-pixel 203. Therefore, the charge generation layer 129 of the light-emitting function layer 120 can be disconnected at the first annular partition part 141, can be disconnected at the second annular partition part 142 and can be disconnected at the third annular partition part 143, and the first annular partition part 141 can separate two adjacent second color sub-pixels 202 from other sub-pixels, thus avoiding crosstalk between the second color sub-pixels and adjacent sub-pixels; the first annular partition part 141 can separate the first color sub-pixel 201 from other sub-pixels, thereby avoiding crosstalk between the first color sub-pixel and adjacent sub-pixels; and the third annular partition part 143 can separate the third color sub-pixel 203 from other sub-pixels, so that crosstalk between the third color sub-pixel and adjacent sub-pixels can be avoided.

In some examples, as illustrated by FIG. 9, two annular partition parts are provided between any two adjacent sub-pixels 200, so that crosstalk between the adjacent sub-pixels can be further avoided.

In some examples, as illustrated by FIG. 9, a plurality of sub-pixels 200 are divided into a plurality of sub-pixel groups 350, and each sub-pixel group 350 includes one first color sub-pixel 201, two second color sub-pixels 202 and one third color sub-pixel 203; in each sub-pixel group 350, the one first color sub-pixel 201 and the one third color sub-pixel 203 are arranged along the first direction, and the two second color sub-pixels 202 are arranged adjacent to each other in the second direction and located between the one first color sub-pixel 201 and the one third color sub-pixel 203. It should be noted that the above-mentioned concept of pixel group is only used to describe the pixel arrangement of the structure of the plurality of sub-pixels, and it is not limited that a pixel group is used to display a pixel point or is driven by the same gate line.

For example, as illustrated by FIG. 9, the four sub-pixels in the dashed frame 360 may be driven by the same gate line. Of course, the embodiments of the present disclosure include but are not limited to this case, and the driving of sub-pixels can be determined according to actual needs.

FIG. 10 is a schematic planar view of another display substrate provided by an embodiment of the present disclosure. As illustrated by FIG. 10, the plurality of sub-pixels 200 includes a plurality of first color sub-pixels 201, a plurality of second color sub-pixels 202 and a plurality of third color sub-pixels 203. The partition structure 140 includes a plurality of first annular partition parts 141, a plurality of second annular partition parts 142 and a plurality of third annular partition parts 143. Each first annular partition part 141 is around two adjacent second color sub-pixels 202; each second annular partition part 142 is around one first color sub-pixel 201; and each third annular partition part 143 is around one third color sub-pixel 203. Therefore, the charge generation layer 129 of the light-emitting function layer 120 can be disconnected at the first annular partition part 141, can be disconnected at the second annular partition part 142 and can be disconnected at the third annular partition part 143, and the first annular partition part 141 can separate two adjacent second color sub-pixels 202 from other sub-pixels, thus avoiding crosstalk between the second color sub-pixels and adjacent sub-pixels; the first annular partition part 141 can separate the first color sub-pixel 201 from other sub-pixels, thereby avoiding crosstalk between the first color sub-pixel and adjacent sub-pixels; and the third annular partition part 143 can separate the third color sub-pixel 203 from other sub-pixels, so that crosstalk between the third color sub-pixel and adjacent sub-pixels can be avoided.

In some examples, as illustrated by FIG. 10, any two adjacent annular partition parts selected from the group consisting of a plurality of first annular partition parts 141, a plurality of second annular partition parts 142 and a plurality of third annular partition parts 143 share a partition edge part. Therefore, only one partition structure is arranged between two adjacent sub-pixels, so that the width of the space between two adjacent sub-pixels can be reduced to improve the pixels per inch.

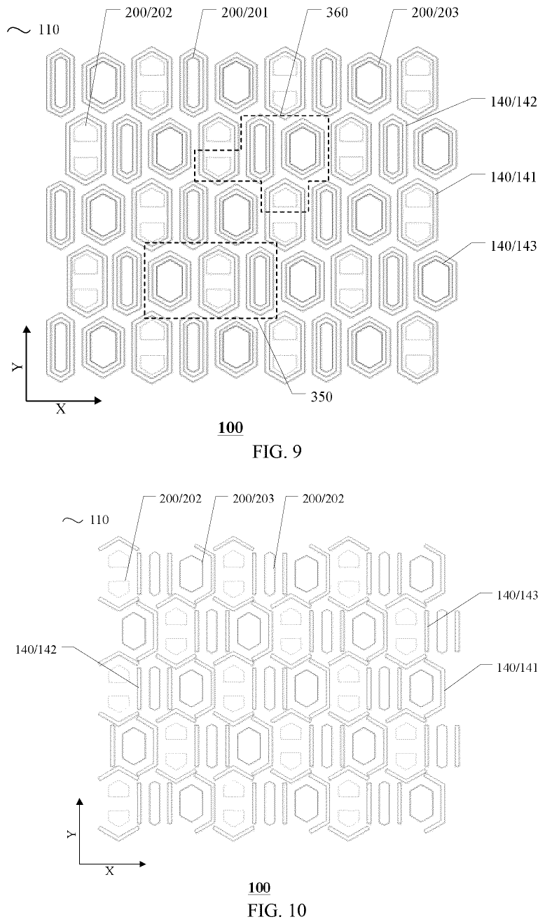

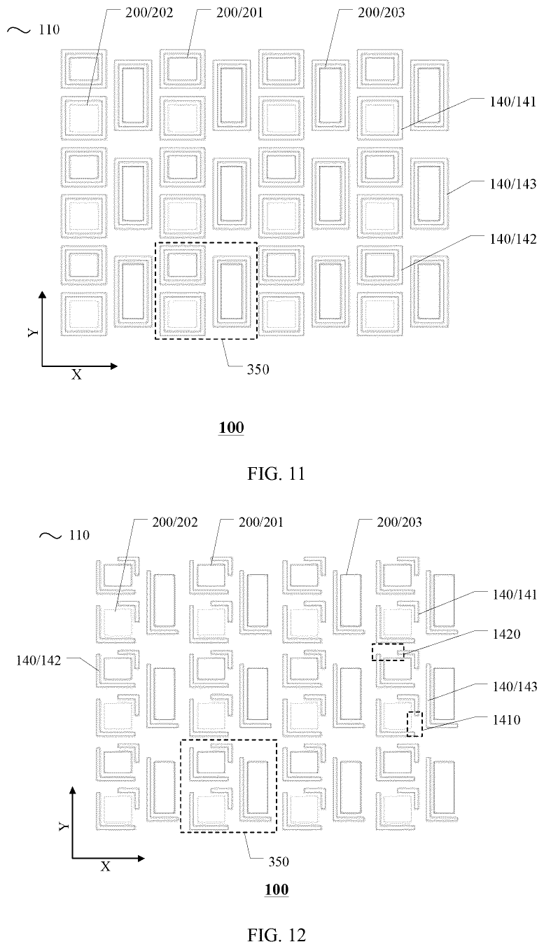

FIG. 11 is a schematic planar view of further another display substrate provided by an embodiment of the present disclosure. As illustrated by FIG. 11, the plurality of sub-pixels 200 includes a plurality of first color sub-pixels 201, a plurality of second color sub-pixels 202 and a plurality of third color sub-pixels 203. The partition structure 140 includes a plurality of first annular partition parts 141 and a plurality of second annular partition parts 142, each first annular partition part 141 is around one second color sub-pixel 202, and each second annular partition part 142 is around one first color sub-pixel 201.

In some examples, as illustrated by FIG. 11, the partition structure 140 includes a plurality of first annular partition parts 141, a plurality of second annular partition parts 142 and a plurality of third annular partition parts 143; each first annular partition part 141 is around one of the second color sub-pixels 202 each second annular partition part 142 is around one first color sub-pixel 201; each third annular partition part 143 is around one third color sub-pixel 203. Therefore, the charge generation layer 129 of the light-emitting function layer 120 can be disconnected at the first annular partition part 141, can be disconnected at the second annular partition part 142 and can be disconnected at the third annular partition part 143, and the first annular partition part 141 can separate the second color sub-pixel 202 from other sub-pixels, thus avoiding crosstalk between the second color sub-pixel and adjacent sub-pixels, the first annular partition part 141 can separate the first color sub-pixel 201 from other sub-pixels, thereby avoiding crosstalk between the first color sub-pixel and adjacent sub-pixels, and the third annular partition part 143 can separate the third color sub-pixel 203 from other sub-pixels, so that crosstalk between the third color sub-pixel and adjacent sub-pixels can be avoided.

In some examples, as illustrated by FIG. 11, two annular partition parts are between any two adjacent sub-pixels 200, so that crosstalk between adjacent sub-pixels can be further avoided.

In some examples, as illustrated by FIG. 11, a plurality of sub-pixels 200 are divided into a plurality of sub-pixel groups 350, and each sub-pixel group 350 includes a first color sub-pixel 201, a second color sub-pixel 202 and a third color sub-pixel 203; in each sub-pixel group 350, the first color sub-pixel 201 or the second color sub-pixel 202 are arranged in the first direction with the third color sub-pixel 203, and the first color sub-pixel 201 and the second color sub-pixel 202 are arranged in a second direction.

FIG. 12 is a schematic planar view of another display substrate provided by an embodiment of the present disclosure. As illustrated by FIG. 12, the plurality of sub-pixels 200 includes a plurality of first color sub-pixels 201, a plurality of second color sub-pixels 202 and a plurality of third color sub-pixels 203. The partition structure 140 includes a plurality of first annular partition parts 141 and a plurality of second annular partition parts 142. A plurality of first annular partition parts 141 are arranged in one-to-one correspondence with a plurality of second color sub-pixels 202, and each first annular partition part 141 is around one of the second color sub-pixels 202. A plurality of second annular partition parts 142 are arranged in one-to-one correspondence with a plurality of first color sub-pixels 201, and each second annular partition part 142 is around one first color sub-pixel 201. Therefore, the charge generation layer 129 of the light-emitting function layer 120 can be disconnected at the first annular partition part 141, can be disconnected at the second annular partition part 142 and can be disconnected at the third annular partition part 143, and the first annular partition part 141 can separate the second color sub-pixel 202 from other sub-pixels, thus avoiding crosstalk between the second color sub-pixel and adjacent sub-pixels. The first annular partition part 141 can separate the first color sub-pixel 201 from other sub-pixels, thereby avoiding crosstalk between the first color sub-pixel and adjacent sub-pixels; the third annular partition part 143 can separate the third color sub-pixel 203 from other sub-pixels, so that crosstalk between the third color sub-pixel and adjacent sub-pixels can be avoided.

In some examples, as illustrated by FIG. 12, a plurality of sub-pixels 200 are divided into a plurality of sub-pixel groups 350, and each sub-pixel group 350 includes one first color sub-pixel 201, one second color sub-pixel 202 and one third color sub-pixel 203; in each sub-pixel group 350, the first color sub-pixel 201 or the second color sub-pixel 202 are arranged in the first direction with the third color sub-pixel 203, and the first color sub-pixel 201 and the second color sub-pixel 202 are arranged in a second direction.

In some examples, as illustrated by FIG. 12, the first annular partition part 141 includes at least one notch 1410, and the second annular partition part 142 includes at least one notch 1420; in this case, the partition structure 140 further includes a plurality of L-shaped partition parts 146, the plurality of L-shaped partition parts 146 are in one-to-one correspondence with a plurality of third color sub-pixels 203, and each L-shaped partition part 146 is around one third color sub-pixel 203. In each pixel group 350, the L-shaped partition part 146 is rightly opposite to both the notch 1410 which is on the first annular partition part 141 and close to the third color sub-pixel 203 and the notch 1420 which is on the second annular partition part 14 and is close to the third color sub-pixel 203. That is, the orthographic projection, of the L-shaped partition part 146 on a reference straight line extending along the second direction Y, overlaps with the orthographic projection, of the notch 1410 which is on the first annular partition part 141 and close to the third color sub-pixel 203, on the reference straight and the orthographic projection, of the notch 1420 which is on the second annular partition part 14 and is close to the third color sub-pixel 203, on the reference straight line, respectively.

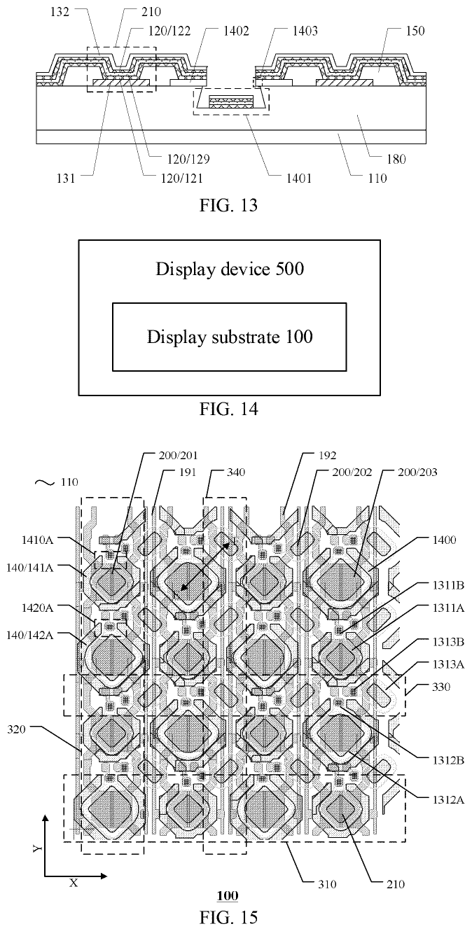

FIG. 13 is a partial sectional view of a display substrate provided by an embodiment of the present disclosure. As illustrated by FIG. 13, the partition structure 140 includes a groove 1401 and a shielding part 1402; the shielding part 1402 is located at the edge of the groove 1401 and protrudes into the groove 1401 to form a protrusion part 1403 covering a part of the opening of the groove 1401, and the conductive sub-layer 129 of the light-emitting function layer 120 is disconnected at the protrusion part 1403 of the shielding part 1402.

For example, as illustrated by FIG. 13, the shielding part 1402 protrudes into the groove 1401 relative to the edge of the groove 1401 to form the protrusion part 1403; in this case, the protrusion part 1403 of the shielding part 1402 is suspended, and the protrusion part 1403 shields the edge part of the opening of the groove 1401.

In some examples, as illustrated by FIG. 13, two edges of the groove 1401 in the arrangement direction of two adjacent sub-pixels 200 are respectively provided with the shielding parts 1402.

In some examples, as illustrated by FIG. 13, the second electrode 132 is disconnected at the position where the partition structure 140 is located.

In some examples, as illustrated by FIG. 13, the display substrate 100 further includes a planarization layer 180; the groove 1401 is arranged in the planarization layer 180; a part of the shielding part 1402 except the protrusion part 1403 may be located between the planarization layer 180 and the pixel definition layer 150.

For example, the ratio of the size, of the protrusion part 1403 protruding into the groove 1401 of the shielding part 1402, to the size of the shielding part 1402 may range from 0.1 to 0.5. For example, the ratio of the size, of the protrusion part 310 protruding into the groove 1401 of the shielding part 1402, to the size of the shielding part 1402 may range from 0.2 to 0.4. For example, the size of the protrusion part 1403 protruding from the shielding part 1402 into the groove 1401 is not less than 0.1 micron. For example, the size of the protrusion part 1403 protruding from the shielding part 1402 into the groove 1401 is not less than 0.2 micron.

For example, the distance between two shielding parts 1402 located between adjacent sub-pixels may range from 2 to 15 microns. For example, the distance between two shielding parts 1402 located between adjacent sub-pixels may range from 5 to 10 microns. For example, the distance between two shielding parts 1402 located between adjacent sub-pixels may range from 3 to 7 microns. For example, the distance between two shielding parts 1402 located between adjacent sub-pixels may range from 4 to 12 microns.

For example, as illustrated by FIG. 13, the shielding part 1402 except the protrusion part 1403 is attached to and in contact with the surface of the planarization layer 180 away from the base substrate 110.

For example, the shielding part 1402 may be made of the same material as the first electrode 131 and located in the same layer. Therefore, the shielding part 1402 may be formed together in the process of patterning the first electrode 131, thereby saving the mask process. Of course, the embodiments of the present disclosure include but are not limited to this case, and the shielding part may also be made of other materials, such as inorganic materials.

For example, the material of the planarization layer 180 may be an organic material, such as resin, acrylic or polyethylene terephthalate, polyimide, polyamide, polycarbonate, epoxy resin, etc.

In some examples, at least one other layer is arranged between the planarization layer 180 and the base substrate 110, the at least one other layer may include any one layer or structure such as gate insulation layer, interlayer insulation layers, pixel circuits (including a thin film transistor and storage capacitor, for example), data line, gate line, power signal line, reset power signal line, reset control signal lines, light emission control signal line, etc.

At least one embodiment of the present disclosure also provides a display device. FIG. 14 is a schematic diagram of a display device provided by an embodiment of the present disclosure. As illustrated by FIG. 14, the display device 500 further includes a display substrate 100. According to the display substrate, the partition structure is arranged between adjacent sub-pixels, and the charge generation layer in the light-emitting function layer is disconnected at the position where the partition structure is located, so that crosstalk between adjacent sub-pixels caused by the charge generation layer with higher conductivity is avoided. Therefore, the display device including the display substrate can also avoid crosstalk between adjacent sub-pixels, thus having higher product yield and higher display quality.

On the other hand, since the display substrate can adopt a design of Tandem EL, the pixel density (pixels per inch) can be improved. Therefore, the display device including the display substrate has the advantages of long service life, low power consumption, high brightness and high resolution.

For example, the display device may be a display device such as an organic light-emitting diode display device, and any product or component with display function such as a TV, a digital camera, a mobile phone, a watch, a tablet computer, a notebook computer, a navigator and the like including the display device, and this embodiment is not limited to these cases.

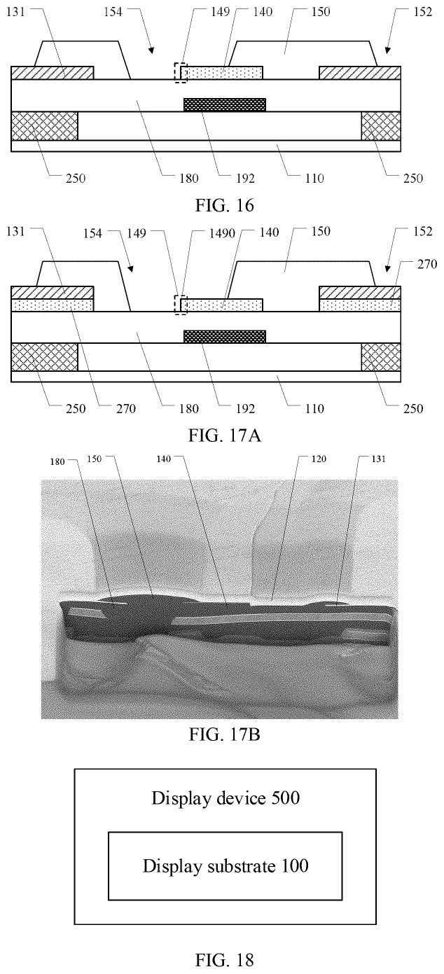

In order to better ensure the continuity of the second electrode while effectively isolating and disconnecting the charge generation layers of adjacent sub-pixels, an embodiment of the present disclosure further provides another display substrate. FIG. 15 is a schematic planar view of another display substrate provided by an embodiment of the present disclosure; FIG. 16 is a schematic cross-sectional view of a display substrate along the line EF in FIG. 15 according to an embodiment of the present disclosure.

As illustrated by FIGS. 15 and 16, the display substrate 100 includes a base substrate 110 and a plurality of sub-pixels 200 located on the base substrate 110; a plurality of sub-pixels 200 are arranged on the base substrate 110, and each sub-pixel 200 includes a light-emitting element 210 and a pixel driving circuit 250 for driving the light-emitting element 210 to emit light. Each light-emitting element 210 includes a light-emitting function layer, a first electrode and a second electrode; the light-emitting function layer may include a plurality of sub-function layers, and the sub-function layers may include a charge generation layer with high conductivity. It should be noted that the cross-sectional structure of the light-emitting element can be referred to the relevant description in FIG. 2, which is not repeated here.

For example, the pixel driving circuit 250 may be electrically connected with the first electrode 131 in the corresponding light-emitting element 210, so that the light-emitting element 210 can be driven to emit light by the pixel driving circuit 250. The first electrode 131 may be an anode and the second electrode 132 may be a cathode; a plurality of sub-pixels 200 may share a second electrode 132, that is, a plurality of sub-pixels 200 may share a cathode.

For example, the cathode may be formed of a material with high conductivity and low work function, and for example, the cathode may be made of a metal material. For example, the anode may be formed of a transparent conductive material with a high work function.

As illustrated by FIGS. 15 and 16, the display substrate 100 further includes a partition structure 140 located on the base substrate 110 and between adjacent sub-pixels 200; in this way, the charge generation layer 129 in the light-emitting function layer 120 is disconnected at the position where the partition structure 140 is located. The plurality of sub-pixels 200 include a plurality of first color sub-pixels 201, a plurality of second color sub-pixels 202 and a plurality of third color sub-pixels 203, and the partition structure 140 includes a plurality of annular partition parts 1400, each of the annular partition parts 1400 surrounds one selected from the group consisting of one first color sub-pixels 201, one second color sub-pixel 202 and one third color sub-pixel 203; that is, each annular partition part 1400 surrounds one first color sub-pixel 201, or one second color sub-pixel 202, or one third color sub-pixel 203. In addition, the above-mentioned annular partition part may be in a shape of a closed ring or a non-closed ring, for example, a ring including at least one notch.

In the display substrate provided by the embodiment of the present disclosure, the partition structure is arranged between adjacent sub-pixels, and the charge generation layer in the light-emitting function layer is disconnected at the position where the partition structure is located, thereby avoiding the crosstalk between adjacent sub-pixels caused by the charge generation layer with higher conductivity. Moreover, because the partition structure comprises a plurality of annular partition parts, each annular partition part surrounds one first color subpixel, or one second color sub-pixel or one third color subpixel, the partition structure can realize the partition and disconnection between most adjacent subpixels through simple annular partition parts, thereby avoiding the crosstalk between adjacent subpixels. On the other hand, because the crosstalk between adjacent sub-pixels in the display substrate can be avoided through the partition structure, the display substrate can realize the improvement of pixels per inch while adopting a design of Tandem EL. Therefore, the display substrate has the advantages of long service life, low power consumption, high brightness and high resolution.

In some examples, as illustrated by FIGS. 15 and 16, in the display substrate 100, the number of the second color sub-pixels 202 is greater than the number of the first color sub-pixels 201; alternatively, the number of the second color sub-pixels 202 is greater than the number of the third color sub-pixels 203; alternatively, the number of the second color sub-pixels 202 is greater than the number of the first color sub-pixels 201 and the number of the third color sub-pixels 203. Therefore, by arranging the first annular pixel partition part 141A outside the first color sub-pixel 201 with a smaller number and arranging the second annular pixel partition part 142B outside the third color sub-pixel 203 with a smaller number, most of the adjacent sub-pixels on the display substrate can be separated, so that the crosstalk between adjacent sub-pixels can be effectively avoided.

In some examples, as illustrated by FIGS. 15 and 16, in the display substrate 100, the number of the second color sub-pixels 202 is approximately twice that of the first color sub-pixels 201 or the third color sub-pixels 203.

In some examples, as illustrated by FIGS. 15 and 16, the partition structure 140 also does not need to be provided with the strip-shaped partition part as illustrated by FIG. 1, and can also separate the first color sub-pixel and the third color sub-pixel that are adjacent to each other.

In some examples, the light-emitting function layer includes a first light-emitting layer and a second light-emitting layer that are respectively located on two sides of the conductive sub-layer in the direction perpendicular to the base substrate, and the conductive sub-layer is a charge generation layer. Therefore, the display substrate can realize a design of Tandem EL, so it has the advantages of long life, low power consumption and high brightness. It should be noted that the cross-sectional structure of the light-emitting function layer can be referred to the relevant description in FIG. 2, and is not repeated here.

In some examples, the conductivity of the conductive sub-layer 129 is greater than that of the first light-emitting layer 121 and that of the second light-emitting layer 122, and less than that of the second electrode 132.

In some examples, as illustrated by FIGS. 15 and 16, the first light-emitting layer 121 is located on the side of the conductive sub-layer 129 close to the base substrate 110; The second light-emitting layer 122 is located on the side of the conductive sub-layer 129 away from the base substrate 110.

In some examples, as illustrated by FIGS. 15 and 16, a plurality of annular partition parts 1400 include a plurality of first annular pixel partition parts 141A and a plurality of second annular pixel partition parts 142A, the plurality of first annular pixel partition parts 141A are arranged correspondingly to the plurality of first color subpixels 201, and the plurality of second annular pixel partition parts 142A are arranged correspondingly to the plurality of third color subpixels 203; each first annular pixel partition part 141A surrounds one first color sub-pixel 201, and each second annular pixel partition part 142A surrounds one third color sub-pixel 203. Therefore, the plurality of first annular pixel partition parts 141A can separate the first color subpixels 201 from other adjacent subpixels, and the plurality of second annular pixel partition parts 142 can separate the plurality of third color subpixels 203 from other adjacent subpixels, so that the crosstalk between adjacent subpixels in the display substrate can be effectively avoided.

In some examples, as illustrated by FIGS. 15 and 16, the partition structure 140 between adjacent first color sub-pixels 201 and second color sub-pixels 202 only includes a first annular pixel partition part 141A, and the partition structure 140 between the third color sub-pixel 203 and the second color sub-pixel 202 that are adjacent to each other only includes a second annular pixel partition part 142A. In this case, there is no need to arrange a ring-shaped partition structure around the second color sub-pixel, and the second electrode may be continuously arranged around the second color sub-pixel. Therefore, in the display substrate, the charge generation layers of adjacent sub-pixels can be effectively isolated and disconnected through the partition structure, and meanwhile, the continuity of the second electrode is maximized, thereby facilitating the transmission of signals on the cathode.

In some examples, as illustrated by FIGS. 15 and 16, the first annular pixel partition part 141A includes a notch 1410A, the notch 1410A is located on the extension line of the diagonal line of the effective light-emitting region of the first color sub-pixel 201. The first electrode 131 of the first color sub-pixel 201 includes a first body part 1311A and a first connection part 1311B, the first connection part 1311B is connected to the first body part 1311A and configured to be connected to the pixel driving circuit 250; the first connection part 1311B is located at the position where the notch 1410A of the first annular pixel partition part 141A is located.

In this case, the notch of the first annular pixel partition part can be used to arrange the first connection part, and the first connection part is used to connect with the corresponding pixel driving circuit. In the case where the pixel density (pixels per inch) of the display substrate is high and the sub-pixels are arranged closely, the space between the opposite edges of the effective light-emitting regions of adjacent sub-pixels is small, while the space between the opposite corners of the effective light-emitting regions of adjacent sub-pixels is large. By arranging the notch of the first annular pixel partition on the extension line of the diagonal line of the effective light-emitting regions of the first color sub-pixel, the display substrate can make full use of the space between the opposite corners of the effective light-emitting regions of adjacent sub-pixels. On the other hand, in the display substrate, the density of pixel arrangement can be improved while avoiding the crosstalk between adjacent sub-pixels.

In some examples, as illustrated by FIGS. 15 and 16, the first connection part 1311B is located on the extension line of the diagonal of the first body part 1311A, that is, the first connection part 1311B protrudes outward from one corner of the first body part 1311A.

In some examples, as illustrated by FIG. 15, a plurality of first notches 1410A are arranged in an array, forming a first notch row and a first notch column respectively along a first direction X and a second direction Y; the first notch row extends along the first direction, and the first notch column extends along the second direction; the second notches 1420A are arranged in an array, forming a second notch row and a second notch column respectively along the first direction X and the second direction Y; the second notch row extends along the first direction X, and the second notch column extends along the second direction Y; the first notch row and the second notch row are approximately parallel, and the first notch column and the second notch column are approximately parallel.

In some examples, as illustrated by FIG. 15, the first notch row is located between the first color sub-pixel 201 and the third color sub-pixel 203, and the second notch row is located between the first color sub-pixel 201 and the third color sub-pixel 203.

In some examples, as illustrated by FIGS. 15 and 16, the shape of the orthographic projection of the first body part 1311A on the base substrate 110 includes a rounded rectangle, and the first connection part 1311B protrudes outward from one rounded corner of the first body part 1311A along the extension direction of the diagonal line of the rounded rectangle.

In some examples, as illustrated by FIGS. 15 and 16, the second annular pixel partition part 142A includes a notch 1420A, the notch 1420A is located on the extension line of the diagonal line of the effective light-emitting region of the third color sub-pixel 203. The first electrode 131 of the third color sub-pixel 203 includes a second body part 1312A and a second connection part 1312B, and the second connection part 1312B is connected with the second body part 1312A and configured to be connected with the pixel driving circuit 250; the first connection part 1312B is located at the position where the notch 1420A of the first annular pixel partition part 142A is located.

In this case, the notch of the second annular pixel partition part can be used to arrange the second connection part, and the second connection part is used to connect with the corresponding pixel driving circuit. In the case where the pixel density (pixels per inch) of the display substrate is high and the sub-pixels are arranged closely, the space between the opposite edges of the effective light-emitting regions of adjacent sub-pixels is small, while the space between the opposite corners of the effective light-emitting regions of adjacent sub-pixels is large. By arranging the notch of the second annular pixel partition part on the extension line of the diagonal line of the effective light-emitting region of the third color sub-pixel, the display substrate can make full use of the space between the opposite corners of the effective light-emitting regions of adjacent sub-pixels. On the other hand, in the display substrate, the density of pixel arrangement can be improved while avoiding the crosstalk between adjacent sub-pixels.

In some examples, as illustrated by FIGS. 15 and 16, the second connection part 1312B is located on the extension line of the diagonal of the second body part 1312A, that is, the second connection part 1312B protrudes outward from one corner of the second body part 1312A.

In some examples, as illustrated by FIGS. 15 and 16, the shape of the orthographic projection of the second body part 1312A on the base substrate 110 includes a rounded rectangle, and the second connecting part 1312B protrudes outward from one rounded corner of the second body part 1312A along the extension direction of the diagonal line of the rounded rectangle.

In some examples, as illustrated by FIGS. 15 and 16, the direction in which the first connection part 1311B protrudes from the first body part 1311A is the same as the direction in which the second connection part 1312B protrudes from the second body part 1312A.

In some examples, as illustrated by FIGS. 15 and 16, the first electrode 131 of the second color sub-pixel 202 includes a third body part 1313A and a third connection part 1313B connected to the third body part 1313A and configured to be connected to the pixel driving circuit 250.

In some examples, as illustrated by FIGS. 15 and 16, the third connection part 1313B is located on the extension line of the diagonal line of the third body part 1313A, that is, the third connection part 1313B protrudes outward from one corner of the third body part 1313A.

In some examples, as illustrated by FIGS. 15 and 16, the display substrate 100 further includes a pixel definition layer 150 located on the base substrate 110; part of the pixel definition layer 150 is located on the side of the first electrode 131 away from the base substrate 110; the pixel definition layer 150 includes a plurality of pixel openings 152 and a pixel spacing opening 154; a plurality of pixel openings 152 are in one-to-one correspondence with a plurality of sub-pixels 200 to define the effective light-emitting regions of the plurality of sub-pixels 200; the pixel opening 152 is configured to expose the first electrode 131 so that it is convenient for the first electrode 131 to be in contact with the subsequently formed light-emitting function layer 120. The pixel spacing opening 154 is located between adjacent first electrodes 131, and at least part of the partition structure 140 is located between the pixel definition layer 150 and the base substrate 110, that is, at least part of the partition structure 140 is covered by the pixel definition layer 150.

In the arrangement direction of the adjacent sub-pixels, because at least part of the partition structure is located between the pixel definition layer and the base substrate, the charge generation layer in the light-emitting function layer is only disconnected once at the position where the partition structure is located outside the pixel definition layer; similarly, the second electrode is only disconnected once at the position where the partition structure is located outside the pixel definition layer, but not being disconnected twice at two sides of the partition structure in the arrangement direction of the adjacent sub-pixels. Therefore, the continuity of the second electrode can be better maintained, so that the signals on the cathode can be better transmitted. In addition, the second electrode is only disconnected once at the position where the partition structure is located outside the pixel definition layer, and the second electrode can also reduce or even avoid the formation of a tip structure, thus avoiding the tip discharge phenomenon. It should be noted that the above-mentioned arrangement direction of the adjacent sub-pixels may be the extension direction of the connection line of the brightness centers of the effective light-emitting regions of the adjacent sub-pixels.

In some examples, as illustrated by FIGS. 15 and 16, in the arrangement direction of the adjacent sub-pixels, one side edge of the partition structure 140 in the arrangement direction is located between the pixel definition layer 150 and the base substrate 110, while the other side edge of the partition structure 140 in the arrangement direction is located in the pixel spacing opening 154. In this case, the second electrode is also disconnected only once at the side edge of the partition structure located in the pixel spacing opening, but not being disconnected twice at two sides of the partition structure in the arrangement direction of the adjacent sub-pixels. Therefore, the continuity of the second electrode can be better maintained, so that the signals on the cathode can be better transmitted.

In some examples, as illustrated by FIGS. 15 and 16, in the arrangement direction of the adjacent sub-pixels, one side of the partition structure 140 in the arrangement direction includes a partition surface 1490, and the included angle between the partition surface 1490 and the plane where the base substrate 110 is located ranges from 80 degrees to 100 degrees. Therefore, the partition surface can effectively disconnect the charge generation layer. Of course, the partition structure provided by the embodiment of the present disclosure may also adopt other structures as long as the charge generation layer can be disconnected.

In some examples, as illustrated by FIGS. 15 and 16, the dimension of the partition structure 140 in the direction perpendicular to the base substrate 110 ranges from 500 Å to 1500 Å. Of course, the embodiments of the present disclosure include but are not limited to this case, and the size of the partition structure in the direction perpendicular to the base substrate may be determined according to the actual situation.

For example, the material of the pixel definition layer may include an organic material, such as polyimide, acrylic or polyethylene terephthalate.

In some examples, as illustrated by FIG. 15, a plurality of first color subpixels 201 and a plurality of third color subpixels 203 are alternately arranged in both the first direction and the second direction to form a plurality of first pixel rows 310 and a plurality of first pixel columns 320, and a plurality of second color subpixels 202 are arranged in an array in both the first direction and the second direction to form a plurality of second pixel rows 330 and a plurality of second pixel columns 340. A plurality of first pixel rows 310 and a plurality of second pixel rows 330 are alternately arranged in the second direction and staggered in the first direction, and a plurality of first pixel columns 320 and a plurality of second pixel columns 340 are alternately arranged in the first direction and staggered in the second direction. The partition structure 140 is located between the first color sub-pixel 201 and the third color sub-pixel 203 that are adjacent to each other, and/or between the second color sub-pixel 202 and the third color sub-pixel 203 that are adjacent to each other, and/or between the first color sub-pixel 201 and the second color sub-pixel 202 that are adjacent to each other.

In some examples, the light-emitting efficiency of the third color sub-pixel is less than that of the second color subpixel.

For example, the first color sub-pixel 201 is configured to emit red light, the second color sub-pixel 202 is configured to emit green light, and the third color sub-pixel 203 is configured to emit blue light. Of course, embodiments of the present disclosure include but are not limited to this case.

In some examples, as illustrated by FIG. 15, the area of the orthographic projection of the effective light-emitting region of the third color sub-pixel 203 on the base substrate 110 is larger than that of the effective light-emitting region of the first color sub-pixel 201 on the base substrate 110; the area of the orthographic projection of the effective light-emitting region of the first color sub-pixel 201 on the base substrate 110 is larger than that of the effective light-emitting region of the second color sub-pixel 202 on the base substrate 110. Of course, the embodiments of the present disclosure include but are not limited to this case, and the area of the effective light-emitting region of each sub-pixel may be determined according to actual needs.

In some examples, as illustrated by FIGS. 15 and 16, the display substrate 100 further includes a planarization layer 180, a plurality of data lines 191 and a plurality of power lines 192; the planarization layer 180 is located on the side of the first electrode 131 close to the base substrate 110, that is, the first electrode 131 is located on the side of the planarization layer 180 away from the base substrate 110; the plurality of data lines 191 are located between the planarization layer 180 and the base substrate 110, and the plurality of data lines 191 extend in the first direction and are arranged in the second direction, and the first direction and the second direction intersect each other; the plurality of power lines 192 are located between the planarization layer 180 and the base substrate 110, and extend in the first direction and are arranged in the second direction; in the direction perpendicular to the base substrate 110, the partition structure 140 overlaps with at least one of the data line 191 and the power line 192.

In some examples, as illustrated by FIG. 15, a plurality of data lines 191 and a plurality of power lines 192 are alternately arranged.

FIG. 17A is a partial cross-sectional view of another display substrate provided by an embodiment of the present disclosure. As illustrated by FIG. 17A, the display substrate 100 further includes a planarization layer 180 and a protection structure 270; the planarization layer 180 is located between the base substrate 110 and the first electrode 131; the protection structure 270 is located between the planarization layer 180 and the first electrode 131.

In the manufacturing process of the display substrate, the partition structure is formed after the formation of the planarization layer, and an etching process is required; although the etching process is selective, it will still adversely affect the flatness of the planarization layer, resulting in poor flatness of the first electrode formed on the planarization layer, thus affecting the display effect. However, in the display substrate shown in FIG. 17A, the protection structure is formed between the planarization layer and the first electrode, and the planarization layer below the first electrode is protected from being etched in the etching process of the partition structure by the protection structure, so that the flatness of the planarization layer below the first electrode can be ensured, and then the flatness of the first electrode can be ensured and the display quality can be improved.

In some examples, as illustrated by FIG. 17A, the protection structure 270 and the partition structure 140 are arranged in the same layer, so the protection structure 270 can protect the planarization layer under the first electrode from being etched while forming the protection structure 270. In addition, there is no need to add additional films in the protection structure or add additional mask processes, thus reducing the cost.

In some examples, the protection structure and the partition structure are made of the same material and formed through the same patterning process.

In some examples, as illustrated by FIG. 17A, the orthographic projection of the first electrode 131 on the base substrate 110 falls within the orthographic projection of the protection structure 270 on the base substrate 110. Therefore, the protection structure 270 can fully protect the planarization layer below the first electrode, thus ensuring the flatness of the whole first electrode.

FIG. 17B is a cross-sectional electron microscope view of a display substrate provided by an embodiment of the present disclosure. As illustrated by FIG. 17B, in the arrangement direction of the adjacent sub-pixels 200, one side edge of the partition structure 140 in the arrangement direction is located between the pixel definition layer 150 and the base substrate 110, while the other side edge of the partition structure 140 in the arrangement direction is located in the pixel spacing opening. In this case, the one side edge of the partition structure can play a role of partition and disconnection, while the other side edge is covered by the pixel definition layer. The second electrode is also disconnected only once at the side edge of the partition structure located in the pixel spacing opening, and not being disconnected twice at two sides of the partition structure in the arrangement direction of the adjacent sub-pixels. Therefore, the continuity of the second electrode can be better maintained, so that the signals on the cathode can be better transmitted.

At least one embodiment of the present disclosure also provides a display device. FIG. 18 is a schematic diagram of a display device provided by an embodiment of the present disclosure. As illustrated by FIG. 18, the display device 500 further includes a display substrate 100. According to the display substrate, the partition structure is arranged between adjacent sub-pixels, and the charge generation layer in the light-emitting function layer is disconnected at the position where the partition structure is located, so that the crosstalk between adjacent sub-pixels caused by the charge generation layer with higher conductivity is avoided. Therefore, the display device including the display substrate can also avoid crosstalk between adjacent sub-pixels, thus having higher product yield and higher display quality.

On the other hand, because the display substrate can adopt a design of Tandem EL, the pixels per inch can be improved. Therefore, the display device including the display substrate has the advantages of long service life, low power consumption, high brightness and high resolution.

For example, the display device may be a display device such as an organic light-emitting diode display device, and any product or component with display function such as a TV, a digital camera, a mobile phone, a watch, a tablet computer, a notebook computer, a navigator, etc. including the display device, and this embodiment is not limited to these cases.

An embodiment of the present disclosure further provides a method for manufacturing a display substrate, which is used for manufacturing the display substrate mentioned above. The manufacturing method comprises the following steps: forming a plurality of first electrodes on a base substrate; forming a partition structure on the base substrate; forming a light-emitting function layer on a side, of both the partition structure and the plurality of first electrodes, away from the base substrate, in which the light-emitting function layer comprises an conductive sub-layer; and forming a second electrode on a side of the light-emitting function layer away from the base substrate, in which the second electrode, the light-emitting function layer and the plurality of first electrodes form light-emitting elements of a plurality of sub-pixels, the partition structure is located between adjacent sub-pixels, the conductive sub-layer in the light-emitting function layer is disconnected at the position where the partition structure is located, and the plurality of sub-pixels comprise a plurality of first color sub-pixels, a plurality of second color sub-pixels and a plurality of third color sub-pixels, and the partition structure comprises a plurality of annular partition parts which surround one selected from the group consisting of one first color sub-pixel, one second color sub-pixel, and one third color sub-pixel.

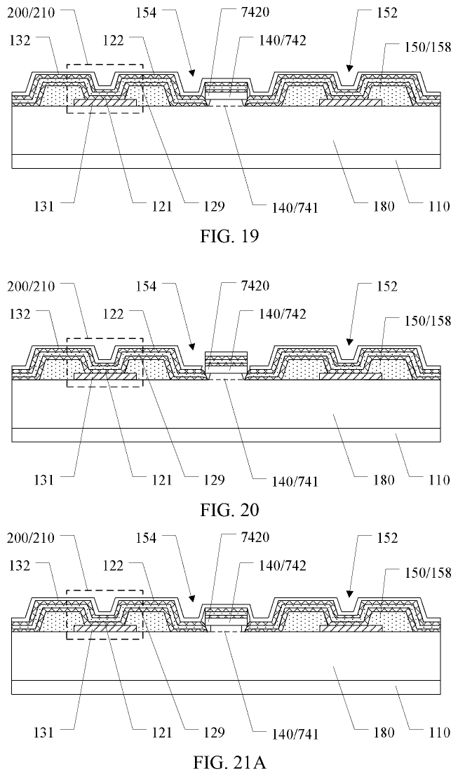

An embodiment of the present disclosure provides a display substrate. FIG. 19 is a partial cross-sectional schematic view of a display substrate provided by an embodiment of the present disclosure. As illustrated by FIG. 19, the display substrate 100 includes a base substrate 110 and a plurality of sub-pixels 200; a plurality of sub-pixels 200 are located on the base substrate 110, and each sub-pixel 200 includes a light-emitting element 210; each light-emitting element 210 includes a light-emitting function layer 120, and a first electrode 131 and a second electrode 132 that are respectively located on two sides of the light-emitting function layer 120, with the first electrode 131 located between the light-emitting function layer 120 and the base substrate 110; at least part of the second electrode 132 is located on the side of the light-emitting function layer 120 away from the first electrode 131; that is, the first electrode 131 and the second electrode 132 are respectively located on two sides of the light-emitting function layer 120 in the direction perpendicular to the light-emitting function layer 120. The light-emitting function layer 120 includes a plurality of sub-function layers, and the sub-function layers include a conductive sub-layer 129 with high conductivity. It should be noted that the above-mentioned light-emitting function layers include not only films that directly emit light, but also function films that assist light emission, such as hole transport layer and electron transport layer.

For example, the conductive sub-layer 129 may be a charge generation layer. For example, the first electrode 131 may be an anode and the second electrode 132 may be a cathode. For example, the cathode may be made of a material with high conductivity and low work function, and for example, the cathode may be made of a metal material. For example, the anode may be formed of a transparent conductive material with a high work function.

As illustrated by FIG. 19, the display substrate 100 further includes a partition structure 140, the partition structure 140 is located on the base substrate 110 and between adjacent sub-pixels 200; the charge generation layer 129 in the light-emitting function layer 120 is disconnected at the position where the partition structure 140 is located. It should be noted that the above-mentioned “adjacent sub-pixels” refers that no other sub-pixels are between two sub-pixels.

In the display substrate provided by the embodiment of the present disclosure, the partition structure is arranged between adjacent sub-pixels, and the charge generation layer in the light-emitting function layer is disconnected at the position where the partition structure is located, thereby avoiding the crosstalk between adjacent sub-pixels caused by the charge generation layer with higher conductivity. On the other hand, because the display substrate can avoid crosstalk between adjacent sub-pixels through the partition structure, the pixels per inch of the display substrate can be improved while the display substrate adopts a design of Tandem EL. Therefore, the display substrate has the advantages of long service life, low power consumption, high brightness and high resolution.

In some examples, as illustrated by FIG. 19, each partition structure 140 includes a first sub-partition structure 741 and a second sub-partition structure 742 which are stacked; the first sub-partition structure 741 is located between the second sub-partition structure 742 and the base substrate 110, and the material of the second sub-partition structure 742 includes an inorganic non-metallic material.

In some examples, as illustrated by FIG. 19, in the arrangement direction of adjacent sub-pixels 200, the edge of the second sub-partition structure 742 in the partition structure 140 between the adjacent sub-pixels 200 protrudes relative to the edge of the first sub-partition structure 741 to form a partition protrusion part 7420, at least one of a plurality of sub-function layers included in the light-emitting function layer 120 is disconnected at the partition protrusion part 7420. According to the embodiment of the present disclosure, by arranging the partition structure between adjacent sub-pixels in the display substrate, at least one layer of the light-emitting function layer can be disconnected at the partition protrusion part of the second sub-partition structure, which is beneficial to reducing the probability of crosstalk between adjacent sub-pixels.

For example, as illustrated by FIG. 19, a plurality of sub-pixels 200 may include two adjacent sub-pixels 200. For example, at least one edge of the second sub-partition structure 742 protrudes relative to the corresponding edge of the first sub-partition structure 741 to form at least one partition protrusion part 7420.

For example, as illustrated by FIG. 19, both edges of the second sub-partition structure 742 protrude relative to the corresponding edges of the first sub-partition structure 741 to form two partition protrusion parts 7420.

FIG. 19 schematically shows the case that one partition structure 140 is arranged between two adjacent sub-pixels 200, and the partition structure 140 includes two partition protrusion parts 7420, but it is not limited to this case. Two or more partition structures may also be arranged between two adjacent sub-pixels, and each partition structure includes at least one partition protrusion part. By setting the number of the partition structures and the number of the partition protrusion parts, at least one sub-function layer of the light-emitting function layer can be partitioned and disconnected by the partition structure.

For example, as illustrated by FIG. 19, the orthographic projection of the surface of the first sub-partition structure 741 facing the second sub-partition structure 742 on the base substrate 110 is completely located in the orthographic projection of the surface of the second sub-partition structure 742 facing the base substrate 110. For example, the size of the second sub-partition structure 742 in the arrangement direction of adjacent sub-pixels is larger than the size of the surface of the first sub-partition structure 741 facing the second sub-partition structure 742 in the arrangement direction of adjacent sub-pixels.

For example, as illustrated by FIG. 19, in the direction perpendicular to the base substrate 110, the thickness of the first sub-partition structure 741 is greater than that of the second sub-partition structure 742.

For example, as illustrated by FIG. 19, the light-emitting function layer 120 may include a first light-emitting layer 121, a charge generation layer (CGL) 129 and a second light-emitting layer 122, and the charge generation layer 129 is located between the first light-emitting layer 121 and the second light-emitting layer 122. The charge generation layer has strong conductivity, which can make the light-emitting function layer have the advantages of long life, low power consumption and high brightness. For example, compared with the light-emitting function layer without the charge generation layer, the sub-pixel can nearly double the light-emitting brightness by setting the charge generation layer in the light-emitting function layer.

For example, in each sub-pixel 200, the light-emitting function layer 120 may further include a hole injection layer (HIL), a hole transport layer (HTL), an electron transport layer (ETL) and an electron injection layer (EIL).

For example, the hole injection layer, the hole transport layer, the electron transport layer, the electron injection layer and the charge generation layer are all common layers of a plurality of sub-pixels, which can be called common layers. For example, at least one sub-function layer in the light-emitting function layer that is disconnected at the partition protrusion part may be at least one of the above-mentioned common layers. By disconnecting at least one sub-function layer in the common layer at the position of the partition protrusion part which is between adjacent sub-pixels, the probability of crosstalk between adjacent sub-pixels can be reduced.

For example, in the same one sub-pixel 200, the first light-emitting layer 121 and the second light-emitting layer 122 may be light-emitting layers emitting the same color. For example, the first light-emitting layer 121 (or the second light-emitting layer 122) in the sub-pixel 200 that emits light of different colors. Of course, the embodiment of the present disclosure is not limited to this case. For example, in the same one sub-pixel 200, the first light-emitting layer 121 and the second light-emitting layer 122 may be light-emitting layers emitting different colors. By setting the light-emitting layers emitting different colors in the same sub-pixel 200, the light emitted by the multi-layer light-emitting layers included in the sub-pixel 200 can be mixed into white light, and the color of the emitted light of each sub-pixel can be adjusted by setting the color filter layer.

For example, in adjacent sub-pixels 200, the light-emitting layers located on the same side of the charge generation layer 129 may be arranged at intervals from each other, or may overlap with each other or exactly connect with each other at the interval between two sub-pixels 200, which is not limited by the embodiment of the present disclosure.

For example, the material of the charge generation layer 129 may be the same as that of the electron transport layer. For example, the materials of the electron transport layer may include aromatic heterocyclic compounds, such as imidazole derivatives such as benzimidazole derivatives, imidazopyridine derivatives, benzimidazole phenanthridine derivatives, etc., or triazine derivatives, such as pyrimidine derivatives, triazine derivatives, etc., or compounds containing nitrogen-containing six-membered ring structures (including compounds with phosphine oxide substituents on heterocyclic rings) such as quinoline derivatives, isoquinoline derivatives, phenanthroline derivatives, etc.

For example, the material of the charge generation layer 129 may be a material containing phosphorus oxygen groups or a material containing triazine.

For example, in the case where the partition structure 140 is not provided between the two adjacent sub-pixels 200, the common layers such as the charge generation layer 129 in the light-emitting function layer 120 of the two adjacent sub-pixels 200 may be continuous and connected or a whole continuous layer, for example, the charge generation layer 129 has high conductivity, and for a display device with high resolution, the high conductivity of the charge generation layer 129 may easily lead to crosstalk between adjacent sub-pixels 200.

In the display substrate provided by the embodiment of the present disclosure, by arranging the partition structure with partition protrusion parts between the adjacent two sub-pixels, at least one of the light-emitting function layers formed at the partition protrusion parts can be disconnected. At this time, at least one film layer (such as a charge generation layer) among the light-emitting function layers of the adjacent two sub-pixels is arranged at intervals, so that the resistance of the light-emitting function layers between the adjacent two sub-pixels can be increased, thereby reducing the probability of crosstalk between the adjacent two sub-pixels.

For example, as illustrated by FIG. 19, the material of the second sub-partition structure 742 may include any one or more of silicon nitride, silicon oxide or silicon oxynitride.

For example, as illustrated by FIG. 19, the second electrode 132 in a plurality of sub-pixels 200 may be a common electrode shared by a plurality of sub-pixels 200, and the second electrode 132 is a whole continuous film in the case where the partition structure 140 is not provided between two adjacent sub-pixels 200.

For example, as illustrated by FIG. 19, the size of the partition protrusion part 7420 may be in the range of 0.1 microns-5 microns. For example, the size of the partition protrusion part 7420 may be in the range of 0.2 microns-2 microns.

For example, as illustrated by FIG. 19, in the direction perpendicular to the base substrate 110, the ratio of the thickness of the partition structure 140 to the thickness of the light-emitting function layer 120 is in the range of 0.8˜1.2. For example, the ratio of the thickness of the partition structure 140 to the thickness of the light-emitting function layer 120 is in the range of 0.9˜1.1. For example, in the direction perpendicular to the base substrate 110, the thickness of the second sub-partition structure 742 may ranges from 100 angstroms to 10000 angstroms. For example, the thickness of the second sub-partition structure 742 may ranges from 200 angstroms to 1500 angstroms. For example, in the direction perpendicular to the base substrate 110, the thickness of the first sub-partition structure 741 may ranges from 100 angstroms to 10000 angstroms. For example, the thickness of the first sub-partition structure 741 may ranges from 200 angstroms to 2000 angstroms. In an example of the embodiment of the present disclosure, by setting the thickness of the partition structure, for example, setting the ratio of the thickness of the partition structure to the thickness of the light-emitting function layer to be in the range of 0.8-1.2, the light-emitting function layer 120 can be disconnected at the partition protrusion part 7420 of the partition structure 140, while the second electrode 132 remains continuous and uninterrupted, thus preventing the crosstalk between adjacent sub-pixels, and ensuring the uniformity of display at the same time.

For example, the thickness of the partition structure 140 may ranges from 300 angstroms to 5000 angstroms, and the above-mentioned thickness of the partition structure 140 (300 angstroms to 5000 angstroms) can make the light-emitting function layer 120 necessarily disconnect at the edge of the partition structure, and whether the second electrode 132 is disconnected is further determined according to the thickness of the partition structure 140.

By setting the thickness of the partition structure and the size of the partition protrusion part, at least one film of the light-emitting function layer can be disconnected at the partition protrusion part.

FIG. 20 is a schematic cross-sectional view of a partial structure of a display substrate provided by another example of an embodiment of the present disclosure. The display substrate in the example shown in FIG. 20 is different from that in the example shown in FIG. 19 in that the thickness of the partition structure is different. The thickness of the partition structure 140 in the display substrate shown in FIG. 20 is greater than that of the partition structure 140 in the display substrate shown in FIG. 19. For example, as illustrated by FIG. 20, by setting the thickness of the partition structure 140 larger (for example, the ratio of the thickness of the partition structure to the thickness of the light-emitting function layer is greater than 1.5), both the light-emitting function layer and the second electrode are disconnected at the position of the partition structure.

For example, FIG. 19 schematically shows that all the films included in the light-emitting function layer 120 are disconnected at the position of the partition protrusion part 7420 of the partition structure 140, and the second electrode 132 is not disconnected at the position of the partition protrusion part 7420 of the partition structure 140. However, it is not limited to this case. In other examples, the thickness of the partition structure may be set so that a part of the film of the light-emitting function layer that is close to the base substrate is disconnected at the position of the partition protrusion part, and a part of the film of the light-emitting function layer that is away from the base substrate is not disconnected at the position of the partition protrusion part, and the second electrode is not disconnected at the position of the partition protrusion part.

For example, as illustrated by FIG. 19, the material of the first sub-partition structure 741 includes an organic material.

For example, as illustrated by FIG. 19, the display substrate further includes an organic layer 180 which is located between the second sub-partition structure 742 and the base substrate 110. The organic layer 180 may serve as a planarization layer.

For example, as illustrated by FIG. 19, the first sub-partition structure 741 and the organic layer 180 are integral. For example, the first sub-partition structure 741 may be a part of the organic layer 180. For example, the first sub-partition structure 741 may be a part of the organic layer 180 protruding to the side away from the base substrate 110.

For example, as illustrated by FIG. 19, the organic layer 180 includes a planarization (PLN) layer. For example, the material of the first sub-partition structure 741 includes at least one of the group consisting of photoresist, polyimide (PI) resin, acrylic resin, silicon compound or polyacrylic resin.

For example, as illustrated by FIG. 19, the first cross section of the first sub-partition structure 741, which is cut by the plane along the arrangement direction of the adjacent sub-pixels 200 and perpendicular of the base substrate 110, includes a rectangle. For example, the first cross section of the first sub-partition structure 741, which is cut by the plane along the arrangement direction of the adjacent sub-pixels 200 and perpendicular of the base substrate 110, includes a trapezoid, and the angle between the side edge of the trapezoid and the bottom edge of the trapezoid close to the base substrate 110 is not more than 90 degrees.

For example, as illustrated by FIG. 19, the cross section of the first sub-partition structure 741 may be trapezoidal, and the top edge of the trapezoid is located on the side of the bottom edge of the trapezoid away from the base substrate 110, and the included angle between the side edge of the trapezoid and the bottom edge of the trapezoid is not more than 90 degrees.

For example, as illustrated by FIG. 19, the length of the top edge of the trapezoidal cross section of the first sub-partition structure 741 is smaller than the length of the edge of the cross section of the second sub-partition structure 742 close to the base substrate 110, so that the edge of the second sub-partition structure 742 and the edge of the top edge of the first sub-partition structure 741 form an undercut structure, that is, the side edge of the second sub-partition structure 742 includes the partition protrusion part 7420.

FIG. 19 schematically shows that the side edge of the first sub-partition structure 741 is a straight edge, but it is not limited to this case. In the actual manufacturing process, the side edge of the first sub-partition structure 741 may also be a curved edge, for example, the curved edge is bent to the side away from the center of the first sub-partition structure 741, or the curved edge is bent to the side close to the center of the first sub-partition structure 741 in which the curved edge is located. In this case, the included angle between the curved edge of the first sub-partition structure 741 and the bottom edge of the first sub-partition structure 741 may refer to the included angle between the tangent line at the midpoint of the curved edge and the bottom edge of the first sub-partition structure 741, or the included angle between the bottom edge and the tangent line at the intersection of the curved edge and the bottom edge.

For example, as illustrated by FIG. 19, the second cross section of the second sub-partition structure 742, which is cut by the plane along the arrangement direction of the adjacent sub-pixels 200 and perpendicular of the base substrate 110, includes a rectangle or a trapezoid. For example, FIG. 19 schematically shows that the shape of the second cross section of the second sub-partition structure 742 is rectangular. By setting the included angel between the short edge of the second cross section of the second sub-partition structure 742 and the long edge close to the base substrate 110 as a right angle or a substantially right angle (for example, a substantially right angle may refer to that the difference between the included angle between the two edges and 90 degrees is not more than 10 degrees), the light-emitting function layer 120 can be easily disconnected at the edge of the second sub-partition structure 742.

For example, the shape of the second cross section of the second sub-partition structure 742, which is cut by the plane along the arrangement direction of the adjacent sub-pixels 200 and perpendicular of the base substrate 110, may be trapezoidal, and the angle between the side edge of the trapezoid and the bottom edge of the trapezoid away from the base substrate 110 is not less than 70 degrees. In the embodiment of the present disclosure, by setting the included angle between the side edge of the second sub-partition structure 742 and the bottom edge of the trapezoid away from the base substrate, the light-emitting function layer 120 can be disconnected at the side edge of the second sub-partition structure 742.

For example, the shape of the second cross section of the second sub-partition structure 742 may be trapezoidal, and the length of the bottom edge of the trapezoid away from the base substrate 110 is smaller than that of the bottom edge of the trapezoid close to the base substrate 110.

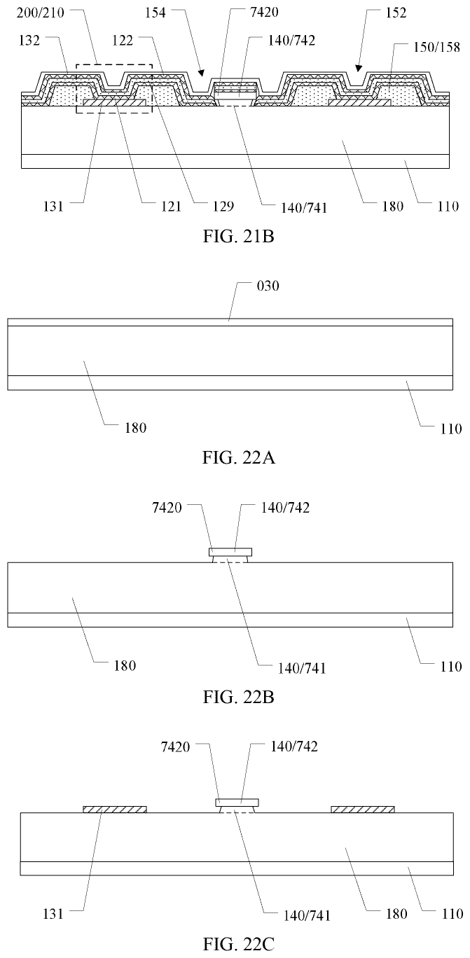

FIG. 21A is a schematic cross-sectional view of a partial structure of a display substrate provided by further another example of an embodiment of the present disclosure. The display substrate shown in FIG. 21A is different from the display substrate shown in FIG. 19 in that the shapes of the first cross section of the first sub-partition structure 741, which is cut by the plane along the arrangement direction of the adjacent sub-pixels 200 and perpendicular of the base substrate 110, are different. For example, as illustrated by FIG. 21A, the shape of the first cross section of the first sub-partition structure 741 which is cut by the plane perpendicular to the base substrate 110 may be rectangular, and the shape of the first cross section of the second sub-partition structure 742 which is cut by the plane perpendicular to the base substrate 110 may also be rectangular, which may facilitate the disconnection of the light-emitting function layer 120 at the position of the edge of the partition structure 140.

FIG. 21B is a schematic cross-sectional view of a partial structure of a display substrate provided by further another example of an embodiment of the present disclosure. The display substrate shown in FIG. 21B is different from the display substrate shown in FIG. 21A in that the shapes of the first cross section of the first sub-partition structure 741, which is cut by the plane along the arrangement direction of the adjacent sub-pixels 200 and perpendicular of the base substrate 110, are different. For example, as illustrated by FIG. 21B, the shape of the first cross section of the first sub-partition structure 741 which is cut by the plane perpendicular to the base substrate 110 may be trapezoidal, and the length of the bottom edge of the trapezoid away from the base substrate 110 is greater than the length of the bottom edge of the trapezoid close to the base substrate 110, which may facilitate the disconnection of the light-emitting function layer 120 at the position of the edge of the partition structure 140.

For example, as illustrated by FIGS. 19 to 21B, the first electrode 131 is in contact with a surface of the organic layer 180 away from the base substrate 110. For example, the first electrode 131 may be an anode and the second electrode 132 may be a cathode. For example, the cathode may be made of a material with high conductivity and low work function, and for example, the cathode may be made of a metal material. For example, the anode may be formed of a transparent conductive material with a high work function.

For example, as illustrated by FIGS. 19 to 21B, the display substrate further includes a pixel definition layer 150 located on the side of the organic layer 180 away from the base substrate 110, and the pixel definition layer 150 includes a plurality of first openings 152, the plurality of first openings 152 are arranged in one-to-one correspondence with the plurality of sub-pixels 200 to define light-emitting regions of the plurality of sub-pixels 200, and the first openings 152 are configured to expose the first electrodes 131. For example, at least part of the first electrode 131 is located between the pixel definition layer 150 and the base substrate 110. For example, in the case where the light-emitting function layer 120 is formed in the first opening 152 of the pixel definition layer 150, the light-emitting function layer 120 in the first opening 152 that can be driven, by the first electrode 131 and the second electrode 132 that are respectively located at two sides of the light-emitting function layer 120, to emit light. For example, the light-emitting region may refer to the region where the sub-pixel effectively emits light, and the shape of the light-emitting region refers to a two-dimensional shape, for example, the shape of the light-emitting region may be the same as the shape of the first opening 152 of the pixel definition layer 150.

For example, as illustrated by FIGS. 19 to 21B, the part of the pixel definition layer 150 except the first opening 152 is a pixel definition part, and the material of the pixel definition part may include at least one selected from the group consisting of polyimide, acrylic and polyethylene terephthalate.

For example, as illustrated by FIGS. 19 to 21B, the pixel definition layer 150 further includes a plurality of second openings 154, the plurality of second openings 154 are configured to expose the partition structure 140. For example, a space is provided between the partition structure 140 and the pixel definition part of the pixel definition layer 150.

For example, as illustrated by FIGS. 19 to 21B, the second sub-partition structure 742 includes at least one partition layer. For example, the second sub-partition structure 742 may include a single-layer partition layer, and the material of this single-layer partition layer may be silicon oxide or silicon nitride. For example, the second sub-partition structure 742 may include two partition layers, and the two partition layers are respectively made of silicon oxide and silicon nitride. The embodiment of the present disclosure is not limited to this case, and the second sub-partition structure may include three or more partition layers, and the number of partition layers included in the second sub-partition structure may be determined according to product requirements.

For example, as illustrated by FIGS. 19 to 21B, in the direction perpendicular to the base substrate 110, the thickness of the partition structure 140 is smaller than that of the pixel definition part.

For example, as illustrated by FIGS. 19 to 21B, in the direction parallel to the base substrate 110, the size of the partition protrusion part 7420 is not less than 0.01 micron. For example, in the direction parallel to the base substrate 110, the size of the partition protrusion part 7420 is not less than 0.1 micron. For example, in the direction parallel to the base substrate 110, the size of the partition protrusion part 7420 may range from 0.01 micron to 5 microns. For example, in the direction parallel to the base substrate 110, the size of the partition protrusion part 7420 may range from 0.05 micron to 4 microns. For example, in the direction parallel to the base substrate 110, the size of the partition protrusion part 7420 may range from 0.1 micron to 2 microns.

For example, as illustrated by FIGS. 19 to 21B, the second cross section of the second sub-partition structure 742, which is cut by the plane along the arrangement direction of the adjacent sub-pixels 200 and perpendicular of the base substrate 110, includes a rectangle or a trapezoid. For example, the shape of the second cross section of the second sub-partition structure 742 is rectangular. By setting the short side of the second cross section of the second sub-partition structure 742 as a right angle or a substantially right angle with its long edge close to the base substrate 110 (for example, a substantially right angle may refer to that the difference between the included angle between the two edges and 90 degrees is not more than 10 degrees), it can facilitate the disconnection of the light-emitting function layer 120 at the edge of the second sub-partition structure 742.

For example, the second cross section of the second sub-partition structure 742 may be trapezoidal, and the included angle between the side edge of the trapezoid and the bottom edge of the trapezoid close to the base substrate 110 is not less than 70 degrees. For example, the second cross section may be trapezoidal, and the included angle between the side edge of the trapezoid and the bottom edge of the trapezoid close to the base substrate 110 is not less than 90 degrees, so that the included angle between the side edge of the second sub-partition structure 742 and the bottom edge of the trapezoid away from the base substrate 110 is acute, which may facilitate the disconnection of the light-emitting function layer 120 at the position of the edge of the second sub-partition structure 742.

For example, the display substrate further includes a pixel circuit, and the first electrode 131 of the organic light-emitting element 210 may be connected to one of the source and the drain of the thin film transistor in the pixel circuit through a via hole penetrating the organic layer 180 and other layers. For example, the pixel circuit further includes a storage capacitor. For example, between the organic layer 180 and the base substrate 110, layers or structures such as a gate insulation layer, an interlayer insulation layer, each layer in a pixel circuit, a data line, a gate line, a power signal line, a reset power signal line, a reset control signal line, and a light emission control signal line may also be provided. For example, the layers between the organic layer 180 and the base substrate 110 may include one layer of power signal lines or two layers of power signal lines. For example, a surface of the organic layer 180 facing the base substrate 110 may be in contact with the interlayer insulation layer.

For example, the side of the pixel definition part of the pixel definition layer 150 away from the base substrate 110 may also be provided with a spacer, and the spacer is configured to support the vapor deposition mask plate for manufacturing the light-emitting layer.

For example, an embodiment of the present disclosure provides a manufacturing method for forming a display substrate as illustrated by FIG. 19, which includes forming a plurality of sub-pixels 200 on a base substrate 110, in which forming the sub-pixels 200 includes: sequentially forming a first electrode 131, a light-emitting function layer 120 and a second electrode 132 which are stacked in a direction perpendicular to the base substrate 110; forming a first material layer on the base substrate 110; forming a second material layer on the first material layer, in which the second material layer is an inorganic nonmetallic material layer; simultaneously patterning the first material layer and the second material layer to form the partition structure 140. Forming the partition structure 140 includes: patterning the second material layer to form a second sub-partition structure 742, and at the same time, the part of the first material layer directly below the second sub-partition structure 742 is etched to form a first sub-partition structure 741; in the arrangement direction of adjacent sub-pixels 200, the edge of the second sub-partition structure 742 in the partition structure 140 between the adjacent sub-pixels 200 protrudes relative to the edge of the first sub-partition structure 741 to form a partition protrusion part 7420; the light-emitting function layer 120 is formed after the partition structure 140 is formed, and the light-emitting function layer 120 includes a plurality of films, at least one of the plurality of films of the light-emitting function layer 120 is disconnected at the position of the partition protrusion part 7420.

For example, the second material layer is an organic material layer, and simultaneously patterning the first material layer and the second material layer to form the partition structure 140 includes: etching the second material layer by dry etching method to form the second sub-partition structure 742, and at the same time, the part of the organic material layer directly below the second sub-partition structure 742 is dry etched to form the first sub-partition structure 741.

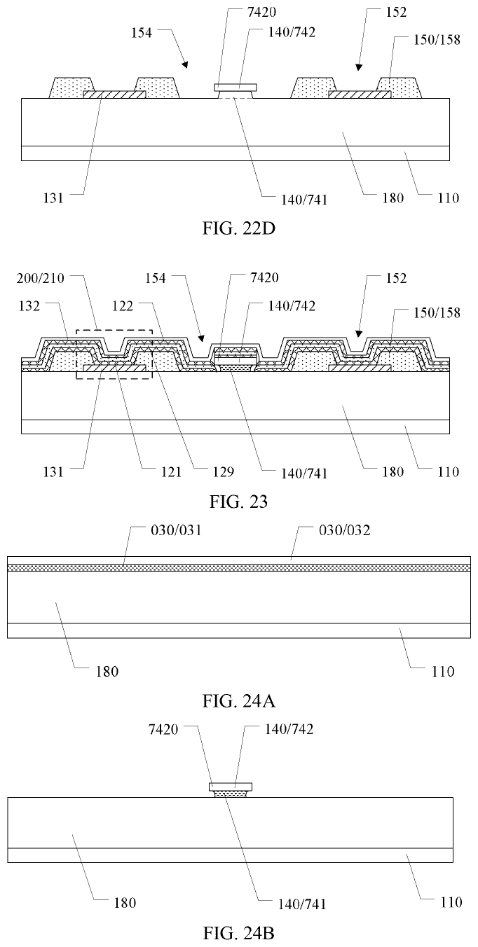

For example, FIGS. 22A to 22D are schematic flow charts of the manufacturing method of the display substrate before forming the display substrate shown in FIG. 19. As illustrated by FIG. 19, FIG. 22A to FIG. 22D, the manufacturing method of the display substrate includes: forming a plurality of sub-pixels 200 on the base substrate 110, in which forming the sub-pixels 200 includes sequentially forming the first electrode 131, the light-emitting function layer 120 and the second electrode 132 which are stacked in the direction perpendicular to the base substrate 110; forming an organic material layer 180 (i.e., a first material layer) on the base substrate 110; forming an inorganic nonmetallic material layer 030 (i.e., a second material layer) on the organic material layer 180; patterning the inorganic nonmetallic material layer 030 to form the second sub-partition structure 742, and at the same time, the part of the organic material layer 180 directly below the second sub-partition structure 742 is etched to form the first sub-partition structure 741. The partition structure 140 includes the first sub-partition structure 741 and the second sub-partition structure 742, and the edge of the second sub-partition structure 742 in the partition structure 140 between adjacent sub-pixels 200 protrudes relative to the edge of the first sub-partition structure 741 to form the partition protrusion part 7420. The light-emitting function layer 120 is formed after the partition structure 140 is formed, and the light-emitting function layer 120 includes a plurality of film layers, at least one of which is disconnected at the partition protrusion part 7420.

For example, as illustrated by FIGS. 19 and 22A, the manufacturing method of the display substrate may include preparing a base substrate 110 on a glass carrier. For example, the base substrate 110 may be a flexible base substrate. For example, forming the base substrate 110 may include sequentially forming a first flexible material layer, a first inorganic material layer, a semiconductor layer, a second flexible material layer and a second inorganic material layer on the glass carrier. The material of the first flexible material layer and the second flexible material layer may be polyimide (PI), or polyethylene terephthalate (PET) or polymer soft film with surface treatment. The materials of the first inorganic material layer and the second inorganic material layer may be silicon nitride (SiNx) or silicon oxide (SiOx) and the like, which are used to improve the water-oxygen resistance of the base substrate. The first inorganic material layer and the second inorganic material layer are also called Barrier layers.

For example, before forming the organic material layer 180, a driving structure layer of the pixel circuit may be formed on the base substrate 110. The driving structure layer includes a plurality of pixel circuits, and each pixel circuit includes a plurality of transistors and at least one storage capacitor. For example, the pixel circuits may adopt designs of 2T1C, or 3T1C or 7T1C and the like. For example, forming the driving structure layer may include sequentially depositing a first insulation film and an active layer film on the base substrate 110, patterning the active layer film through a patterning process to form a first insulation layer covering the entire base substrate 110, and an active layer pattern disposed on the first insulation layer, in which the active layer pattern at least includes an active layer. For example, a second insulation film and a first metal film are sequentially deposited, and the first metal film is patterned by a patterning process to form a second insulation layer covering the active layer pattern and a first gate metal layer pattern arranged on the second insulation layer, in which the first gate metal layer pattern at least includes a gate electrode and a first capacitor electrode. For example, a third insulation film and a second metal film are sequentially deposited, and the second metal film is patterned by a patterning process to form a third insulation layer covering the first gate metal layer and a second gate metal layer pattern arranged on the third insulation layer, in which the second gate metal layer pattern at least includes a second capacitor electrode, and the position of the second capacitor electrode corresponds to the position of the first capacitor electrode. Then, a fourth insulation film is deposited, and the fourth insulation film is patterned by a patterning process to form a fourth insulation layer covering the second gate metal layer. At least two first via holes are formed in the fourth insulation layer, and the part of the fourth insulation layer, the part of the third insulation layer and the part of the second insulation layer that are in the two first via holes are etched away to expose the surface of the active layer of the active layer pattern. Then, a third metal film is deposited and the third metal film is patterned by a patterning process, a source-drain metal layer pattern is formed on the fourth insulation layer, and the source-drain metal layer pattern at least includes a source electrode and a drain electrode located in the display region. The source electrode and the drain electrode may be connected with the active layer in the active layer pattern through the first via holes, respectively.

For example, the first insulation layer, the second insulation layer, the third insulation layer and the fourth insulation layer may be any one or more selected from the group consisting of silicon oxide (SiOx), silicon nitride (SiNx) and silicon oxynitride (SiON), and may be a single layer, a multi-layer or a composite layer. The first insulation layer may be a buffer layer for improving the water and oxygen resistance of the base substrate 110; the second insulation layer and the third insulation layer may be gate insulation (GI) layers; the fourth insulation layer may be an interlayer dielectric (ILD) layer. The first metal thin film, the second metal thin film and the third metal thin film are made of a metal material, such as any one or more selected from the group consisting of silver (Ag), copper (Cu), aluminum (Al), titanium (Ti) and molybdenum (Mo), or an alloy material of the above metals, such as aluminum-neodymium alloy (AlNd) or molybdenum-niobium alloy (MoNb), which may be single-layer structures or multi-layer composite structure, such as Ti/Al/Ti, etc. The active layer film is made of one or more materials such as amorphous indium gallium zinc Oxide (a-IGZO), zinc oxynitride (ZnON), indium zinc tin oxide (IZTO), amorphous silicon (a-Si), polysilicon (p-Si), hexathiophene, polythiophene, etc., that is, the present disclosure is suitable for transistors manufactured based on oxide technology, silicon technology and organic technology.

For example, as illustrated by FIGS. 22A and 22B, after the inorganic nonmetallic material layer 030 is formed, the inorganic nonmetallic material layer 030 is patterned. For example, patterning the inorganic non-metallic material layer 030 includes etching the inorganic non-metallic material layer 030 by dry etching method to form the second sub-partition structure 742, and at the same time, the part of the organic material layer 180 directly below the second sub-partition structure 742 is dry etched to form the first sub-partition structure 741. For example, a mask plate can be used to shield the inorganic non-metallic material layer 030 at the position where the second sub-partition structure 742 is to be formed, so that the part of the inorganic non-metallic material layer 030 at other positions other than the position where the second sub-partition structure 742 is to be formed is etched. During the dry etching of the inorganic non-metallic material layer 030, the etching gas will etch the part of the organic material layer 180 that is not shielded by the mask plate, such that an organic material layer (i.e., the first sub-partition structure 741) with a certain thickness is left right below the inorganic non-metallic material layer (i.e., the second sub-partition structure 742) left after the etching, so that a protrusion located right below the second sub-partition structure 742 is formed on the side of the organic material layer 180 away from the base substrate 110, and this protrusion is the first sub-partition structure 741.

For example, as illustrated by FIGS. 22A and 22B, in the process of dry etching the inorganic nonmetallic material layer 030, the thickness of the organic material layer 180 may range from 100 angstroms to 10000 angstroms, and the thickness of the formed first sub-partition structure 741 may range from 100 angstroms to 10000 angstroms. For example, in the process of dry etching the inorganic nonmetallic material layer 030, the thickness of the organic material layer 180 may range from 200 angstroms to 2000 angstroms, and the thickness of the formed first sub-partition structure 741 may range from 200 angstroms to 2000 angstroms.

For example, as illustrated by FIGS. 19 and 22C, after the partition structure 140 is formed, the first electrode 131 of the sub-pixel is formed on the planarization layer 180 by a patterning process. For example, the first electrode 131 is connected to the drain electrode of the transistor through a second via hole in the planarization layer 180.

For example, the first electrode 131 may adopt a metal material, such as any one or more selected from the group consisting of magnesium (Mg), silver (Ag), copper (Cu), aluminum (Al), titanium (Ti) and molybdenum (Mo), or an alloy material of the above metals, such as aluminum-neodymium alloy (AlNd) or molybdenum-niobium alloy (MoNb), and may be a single-layer structure, or a multi-layer composite structure, such as Ti/Al/Ti, or a stacked structure constituted by metal and transparent conductive materials, such as ITO/Ag/ITO, Mo/AlNd/ITO and other reflective materials.

For example, as illustrated by FIGS. 19 and 22D, after the first electrode 131 is formed, the pixel definition layer 150 may be formed. For example, a pixel defining film is coated on the base substrate 110 formed with the above-mentioned pattern, and the pixel definition layer 150 is formed through mask, exposure and development processes. For example, the pixel definition layer 150 in the display region includes a plurality of pixel definition parts 158, and a first opening 152 or a second opening 154 is formed between adjacent pixel definition parts 401, and the part of the pixel defining film in the first opening 152 and the second opening 154 is removed by the development process, and the first openings 152 respectively expose at least part of the surface of the first electrodes 131 of a plurality of sub-pixels, and the second opening 154 exposes the partition structure 140 in the respective sub-pixel.

For example, after the pixel definition layer 150 is formed, a spacer may be formed on the pixel definition part. For example, a thin film of organic material is coated on the base substrate 110 formed with the above-mentioned pattern, and the spacer is formed through mask, exposure and development processes. The spacer can be used as a support layer and configured to support FMM (Fine Metal Mask) during an evaporation process.

For example, as illustrated by FIG. 19, after the spacer is formed, the light-emitting function layer 120 and the second electrode 132 are sequentially formed. For example, the second electrode 132 may be a transparent cathode. The light-emitting function layer 120 can emit light from the side far away from the base substrate 110 through the transparent cathode to realize top emission. For example, the second electrode 132 may adopt any one or more selected from the group consisting of magnesium (Mg), silver (Ag) and aluminum (Al), or an alloy made of any one or more of the above metals, or a transparent conductive material, such as indium tin oxide (ITO), or a multi-layer composite structure of metal and transparent conductive material.

For example, forming the light-emitting function layer 120 may include: sequentially forming a hole injection layer and a hole transport layer by evaporation using an Open Mask; the first light-emitting layers 131 emitting different colors of light, for example, a blue light-emitting layer, a green light-emitting layer and a red light-emitting layer, are sequentially formed by vapor deposition using an FMM; an electron transport layer, a charge generation layer 133, and a hole transport layer are sequentially formed by evaporation using an Open Mask; the second light-emitting layers 132 emitting different colors of light, for example, a blue light-emitting layer, a green light-emitting layer and a red light-emitting layer, are sequentially formed by vapor deposition using an FMM. The electron transport layer, the second electrode and the optical coupling layer are formed by evaporation in sequence by using an Open Mask. For example, the hole injection layer, the hole transport layer, the electron transport layer, the charge generation layer, the second electrode and the optical coupling layer are all common layers of a plurality of sub-pixels.

For example, as illustrated by FIG. 19, the formed light-emitting function layer 120 will be disconnected at the partition protrusion part 7420 of the partition structure 140, so that a part of the light-emitting function layer 120 located in the second opening 154 of the pixel definition layer 150 is located on the partition structure 140 and the other part is located on the organic layer 180.

For example, after forming the second electrode 132, the manufacturing method of the display substrate further includes forming an encapsulation layer, the encapsulation layer may include a first encapsulation layer, a second encapsulation layer and a third encapsulation layer which are stacked. The first encapsulation layer is made of inorganic material and covers the second electrode 132 in the display region. The second encapsulation layer is made of organic material. The third encapsulation layer is made of inorganic material and covers the first encapsulation layer and the second encapsulation layer. However, this embodiment is not limited to this case. For example, the encapsulation layer may also adopt a five-layer structure of inorganic/organic/inorganic/organic/inorganic.

For example, compared with the display substrate without the partition structure, in the preparation method of the display substrate formed with the partition structure provided by the embodiment of the present disclosure, only one mask process is added, which has a lower impact on the process productivity.

FIG. 23 is a schematic cross-sectional view of a partial structure of a display substrate provided by another example of an embodiment of the present disclosure. The display substrate in the example shown in FIG. 23 is different from the display substrate in the example shown in FIG. 19 in that the material of the first sub-partition structure 741 in the display substrate shown in FIG. 23 includes an inorganic nonmetallic material. The sub-pixels 200, the base substrate 110 and the pixel definition layer 150 in the display substrate shown in FIG. 23 may have the same characteristics as the sub-pixels 200, the base substrate 110 and the pixel definition layer 150 in any one of the display substrates shown in FIGS. 19 to 21B, and will not be described here again.

For example, as illustrated by FIG. 23, the material of the first sub-partition structure 741 is different from that of the second sub-partition structure 742. For example, the material of the second sub-partition structure 742 may include any one or more selected from the group consisting of silicon nitride, silicon oxide and silicon oxynitride, and the material of the first sub-partition structure 741 may also include any one or more selected from the group consisting of silicon nitride, silicon oxide or silicon oxynitride, and the material of the first sub-partition structure 741 is different from that of the second sub-partition structure 742.

For example, as illustrated by FIG. 23, a plurality of sub-pixels 200 may include two adjacent sub-pixels 200 arranged along the arrangement direction of adjacent sub-pixels. For example, at least one edge of the second sub-partition structure 742 protrudes relative to the corresponding edge of the first sub-partition structure 741 to form at least one partition protrusion part 7420. For example, as illustrated by FIG. 23, two side edges of the second sub-partition structure 742 protrude relative to the corresponding edges of the first sub-partition structure 741 to form two partition protrusion parts 7420. For example, two partition protrusion parts 7420 are arranged along the arrangement direction of adjacent sub-pixels.

For example, FIG. 23 schematically shows that one partition structure 140 is arranged between two adjacent sub-pixels 200, and the partition structure 140 includes two partition protrusion parts 7420, but it is not limited to this case, and two or more partition structures may be arranged between two adjacent sub-pixels, and each partition structure includes at least one partition protrusion part. By setting the number of partition structures and the number of partition protrusion parts, at least one layer of the light-emitting function layer can play a better role of being disconnected at the partition structures.

For example, as illustrated by FIG. 23, the orthographic projection of the surface of the first sub-partition structure 741 facing the second sub-partition structure 742 on the base substrate 110 is completely within the orthographic projection of the surface of the second sub-partition structure 742 facing the base substrate 110.

For example, as illustrated by FIG. 23, the thickness of the first sub-partition structure 741 is greater than that of the second sub-partition structure 742 in the direction perpendicular to the base substrate 110.

For example, as illustrated by FIG. 23, in the direction perpendicular to the base substrate 110, the thickness of the partition structure 140 is smaller than that of the pixel definition part 401. For example, a space is provided between the partition structure 140 and the pixel defining portion 401.

For example, as illustrated by FIG. 23, the surface of the organic layer 180 exposed by the second opening 154 of the pixel definition layer 150 on the side away from the base substrate 110 may be a flat surface, that is, the surface of the organic layer 180 on the side away from the base substrate 110 does not include a protrusion. For example, as illustrated by FIG. 23, the first sub-partition structure 741 is disposed on the surface of the organic layer 180 on the side away from the base substrate 110.

For example, as illustrated by FIG. 23, the thickness of the second sub-partition structure 742 is not greater than the thickness of the light-emitting function layer 120 in the direction perpendicular to the base substrate 110. For example, the thickness of the second sub-partition structure 742 may ranges from 500 angstroms to 8000 angstroms.

For example, as illustrated by FIG. 23, in the direction perpendicular to the base substrate 110, the ratio of the thickness of the partition structure 140 to the thickness of the light-emitting function layer 120 is in a range of 0.8˜1.2. For example, the ratio of the thickness of the partition structure 140 to the thickness of the light-emitting function layer 120 is in a range of 0.9˜1.1. In an example of an embodiment of the present disclosure, by setting the thickness of the partition structure, for example, setting the ratio of the thickness of the partition structure to the thickness of the light-emitting function layer to be in a range of 0.8˜1.2, the light-emitting function layer 120 can be disconnected at the partition protrusion part 7420 of the partition structure 140, while the second electrode 132 remains continuous and uninterrupted, thus preventing the crosstalk between adjacent sub-pixels, and ensuring the uniformity of display at the same time.

For example, FIG. 23 schematically shows that all the films included in the light-emitting function layer 120 are disconnected at the partition protrusion part 7420 of the partition structure 140, but it is not limited to this case, and a part of the films of the light-emitting function layer 120 may be disconnected at the partition protrusion part 7420 of the partition structure 140, and another part of the film layers may be continuous at the partition protrusion part 7420. The film disconnected at the partition protrusion part 7420 can be regarded as a film with dislocation. By arranging the film at the partition protrusion part 7420 in a staggered manner to make the film include dislocation, it is beneficial to reduce the lateral crosstalk of the film.

Of course, the example shown in FIG. 23 is not limited to this case, and the thickness of the partition structure may be set to be greater than that of the light-emitting function layer, so that both the light-emitting function layer and the second electrode are disconnected at the edge of the partition structure.

For example, as illustrated by FIG. 23, the first cross section of the first sub-partition structure 741, which is cut by the plane along the arrangement direction of the adjacent sub-pixels 200 and perpendicular of the base substrate 110, includes a rectangle or a trapezoid. For example, the first cross section is trapezoidal, and the length of the bottom edge of the trapezoid away from the base substrate 110 is greater than the length of the bottom edge of the trapezoid close to the base substrate 110. For example, the angle between the side edge of the trapezoid and the bottom edge of the trapezoid close to the base substrate 110 is not less than 70 degrees. For example, in the direction parallel to the base substrate 110, the size of the partition protrusion part 7420 is not less than 0.01 micron. For example, in the direction parallel to the base substrate 110, the size of the partition protrusion part 7420 is not less than 0.1 micron.

For example, as illustrated by FIG. 23, the size of the partition protrusion part 7420 may be in the range of 0.01 microns to 5 microns. For example, the angle between the side edge of the trapezoid and the bottom edge of the trapezoid close to the base substrate 110 is not less than 90 degrees. For example, the size of the partition protrusion part 7420 may be in the range of 0.1 microns to 2 microns.

For example, the side edge of the first sub-partition structure 741 may be a straight edge or a curved edge, for example, the curved edge bends towards the side thereof close to the center of the first sub-partition structure 741. In this case, the included angle between the curved edge of the first sub-partition structure 741 and the bottom edge close to the base substrate 110 can refer to the included angle between the tangent at the midpoint of the curved edge and the bottom edge, or the included angle between the tangent at the intersection of the curved edge and the bottom edge.

In embodiment of that present disclosure, by setting the thickness of the partition structure, the size of the partition protrusion part and the angle formed by the side edge of the first sub-partition structure, at least one film of the light-emitting function layer can be disconnected at the partition protrusion part.

For example, as illustrated by FIG. 23, the second cross section of the second sub-partition structure 742, which is cut by the plane along the arrangement direction of the adjacent sub-pixels 200 and perpendicular of the base substrate 110, includes a rectangle or a trapezoid. For example, the shape of the second cross section of the second sub-partition structure 742 is rectangular. By setting the short edge of the second cross section of the second sub-partition structure 742 as a right angle or a substantially right angle with its long edge close to the base substrate 110 (for example, a substantially right angle may refer to that the difference between the included angle between the two edges and 90 degrees is not more than 10 degrees), it can facilitate the disconnection of the light-emitting function layer 120 at the edge of the second sub-partition structure 742.

For example, the second cross section of the second sub-partition structure 742 may be trapezoidal, and the angle between the side edge of the trapezoid and the bottom edge of the trapezoid close to the base substrate 110 is not less than 70 degrees. For example, the second cross section may be trapezoidal, and the included angle between the side edge of the trapezoid and the bottom edge of the trapezoid close to the base substrate 110 is not less than 90 degrees, so that the included angle between the side edge of the second sub-partition structure 742 and the bottom edge of the trapezoid away from the base substrate 110 is acute, which may facilitate the disconnection of the light-emitting function layer 120 at the edge of the second sub-partition structure 742.

For example, FIG. 23 schematically shows that the first sub-partition structure 741 and the second sub-partition structure 742 include one film, but it is not limited to this case. At least one of the first sub-partition structure 741 and the second sub-partition structure 742 may include a plurality of films, and at least the edge of the second sub-partition structure 742 protrudes relative to the edge of the first sub-partition structure 741 to form a partition protrusion part for disconnecting at least one film of the light-emitting function layer.

In the case where the angel formed by the side edge of the partition structure is large (such as the angle between the side edge of the first cross section and the bottom edge close to the base substrate, and/or the angle between the side edge of the second cross section and the bottom edge of the second cross section close to the base substrate), the deposited thickness of the light-emitting function layer is reduced as a whole, and at least one film of the light-emitting function layer between adjacent sub-pixels is disconnected, so that the resistance of the film is increased, and the crosstalk between adjacent sub-pixels is further reduced.

For example, an embodiment of the present disclosure provides a manufacturing method for forming a display substrate as illustrated by FIG. 23, which includes forming a plurality of sub-pixels 200 on a base substrate 110, in which forming the sub-pixels 200 includes sequentially forming a first electrode 131, a light-emitting function layer 120 and a second electrode 132 which are stacked in a direction perpendicular to the base substrate 110; forming a first material layer on the base substrate 110; forming a second material layer on the first material layer, in which the second material layer is an inorganic nonmetallic material layer; the first material layer and the second material layer are simultaneously patterned to form the partition structure 140. Forming the partition structure 140 includes patterning the second material layer to form a second sub-partition structure 742, and at the same time, etching the part of the first material layer directly below the second sub-partition structure 742 to form a first sub-partition structure 741; in the arrangement direction of adjacent sub-pixels 200, the edge of the second sub-partition structure 742 in the partition structure 140 between the adjacent sub-pixels 200 protrudes relative to the edge of the first sub-partition structure 741 to form a partition protrusion part 7420; the light-emitting function layer 120 is formed after the partition structure 140 is formed, and the light-emitting function layer 120 includes a plurality of films, at least one of the plurality of films is disconnected at the position of the partition protrusion part 7420.

For example, the second material layer is an inorganic material layer, and simultaneously patterning the first material layer and the second material layer to form the partition structure 140 includes simultaneously etching the first material layer and the second material layer with etching solutions with different etching selectivity ratios for the first material layer and the second material layer, in which the etching selectivity ratio of the etching solution to the first material layer is greater than that of the etching solution to the second material layer, so that the edge of the first sub-partition structure 741 formed after the first material layer is etched is retracted relative to the edge of the second sub-partition structure 742 formed after the second material layer is etched, to form an undercut structure.

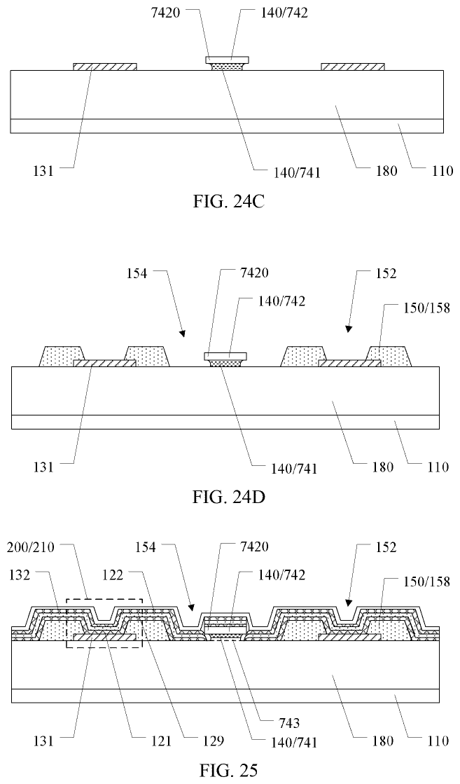

For example, FIGS. 24A to 24D are schematic flow charts of the manufacturing method of the display substrate before forming the display substrate shown in FIG. 23. As illustrated by FIG. 23, FIG. 24A to FIG. 24D, the manufacturing method of the display substrate includes: forming a plurality of sub-pixels 200 on a base substrate 110, in which forming the sub-pixels 200 includes sequentially forming a first electrode 131, a light-emitting function layer 120 and a second electrode 132 which are stacked in a direction perpendicular to the base substrate 110; forming an organic material layer 180 on the base substrate 110; forming an inorganic nonmetallic material layer 030 on the organic material layer 180, in which the inorganic nonmetallic material layer 030 comprises at least two films, such as a film 031 (i.e., a first material layer) and a film 032 (i.e., a second material layer); and patterning the inorganic nonmetallic material layer 030 to form a partition structure 140. The partition structure 140 includes a first sub-partition structure 741 and a second sub-partition structure 742. The first sub-partition structure 741 is located between the second sub-partition structure 742 and the base substrate 110. In the arrangement direction of adjacent sub-pixels 200, the edge of the second sub-partition structure 742 in the partition structure 140 between the adjacent sub-pixels 200 protrudes relative to the edge of the first sub-partition structure 741 to form a partition protrusion part 7420; the light-emitting function layer 120 is formed after the partition structure 140 is formed, and the light-emitting function layer 120 includes a plurality of films, at least one of the plurality of films is disconnected at the partition protrusion part 7420.

For example, the manufacturing method for forming the structures such as the base substrate 110, the sub-pixel 200 and the pixel definition layer 150 in the display substrate shown in FIG. 23 may be the same as the manufacturing method for forming the structures such as the base substrate 110, the sub-pixel 200 and the pixel definition layer 150 in the display substrate shown in FIGS. 22A to 22D, and is not repeated here.

For example, as illustrated by FIGS. 24A and 24B, after the inorganic nonmetallic material layer 030 is formed, the inorganic nonmetallic material layer 030 is patterned. For example, the inorganic nonmetallic material layer 030 may include two films, such as a first inorganic nonmetallic material layer 031 and a second inorganic nonmetallic material layer 032. Patterning the inorganic nonmetallic material layer 030 includes etching the two films included in the inorganic nonmetallic material layer 030 by a wet etching process, in which the etching selectivity of the etching solution or etching gas to the first inorganic nonmetallic material layer 031 is greater than that to the second inorganic nonmetallic material layer 032, so that the edge of the first sub-partition structure 741 formed by etching the first inorganic nonmetallic material layer 031 is retracted relative to the edge of the second sub-partition structure 742 formed by etching the second inorganic nonmetallic material layer 032, to form an undercut structure, that is, to form the partition protrusion part 7420.

For example, as illustrated by FIG. 24C, after the partition structure 140 is formed, the first electrode 131 of the organic light-emitting element 210 of the sub-pixel is patterned on the planarization layer 180. The method and material for forming the first electrode 131 in this example may be the same as that for forming the first electrode 131 shown in FIG. 22C, and are not described here again.

For example, as illustrated by FIG. 24D, after the first electrode 131 is formed, a pixel definition layer 150 may be formed. The method and material for forming the pixel definition layer 150 in this example may be the same as the method and material for forming the pixel definition layer 150 shown in FIG. 22D, and are not described here again. For example, the steps after the pixel definition layer is formed in this example may be the same as those after the pixel definition layer is formed in the display substrate shown in FIG. 19, and are not described here again.

FIG. 25 is a schematic view of a partial cross-sectional structure of a display substrate provided by another example of an embodiment of the present disclosure. The display substrate in the example shown in FIG. 25 is different from the display substrate in the example shown in FIG. 23 in that the partition structure 140 further includes a third sub-partition structure 743. The sub-pixel 200, the base substrate 110 and the pixel definition layer 150 in the display substrate shown in FIG. 25 may have the same features as the sub-pixel 200, the base substrate 110 and the pixel definition layer 150 in any example of the display substrate shown in FIGS. 19 to 21B and FIG. 23, and are not described here again here. The material, shape and size relationship between the first sub-partition structure 741 and the second sub-partition structure 742 in the display substrate shown in FIG. 25 may be the same as those of the first sub-partition structure 741 and the second sub-partition structure 742 in the display substrate shown in FIG. 5, and are not repeated here.

For example, as illustrated by FIG. 25, the third sub-partition structure 743 is located between the first sub-partition structure 741 and the base substrate 110. Along the arrangement direction of adjacent sub-pixels 200, the edge of the first sub-partition structure 741 in the partition structure 140 between adjacent sub-pixels 200 protrudes relative to the edge of the third sub-partition structure 743, and the third sub-partition structure 743 and the organic layer 180 are an integral structure.

For example, as illustrated by FIG. 25, the third sub-partition structure 743 may be a part of the organic layer 180. For example, the third sub-partition structure 743 may be a part of the organic layer 180 protruding to the side away from the base substrate 110. For example, the first sub-partition structure 741 may be located on the part of the organic layer 180 protruding to the side away from the base substrate 110.

For example, as illustrated by FIG. 25, the material of the third sub-partition structure 743 includes at least one selected from the group consisting of photoresist, polyimide (PI) resin, acrylic resin, silicon compound or polyacrylic resin.

For example, as illustrated by FIG. 25, the thickness of the third sub-partition structure 743 may ranges from 100 angstroms to 10000 angstroms. For example, the thickness of the third sub-partition structure 743 may ranges from 200 angstroms to 2000 angstroms.

For example, the cross section of the third sub-partition structure 743, which is cut by the plane along the arrangement direction of the adjacent sub-pixels 200 and perpendicular of the base substrate 110, includes a rectangle. For example, the cross section of the third sub-partition structure 743, which is obtained by cutting the third sub-partition structure 743 by the plane along the arrangement direction of the adjacent sub-pixels 200 and perpendicular of the base substrate 110, includes a trapezoid, and the included angle between the side edge of the trapezoid and the bottom edge of the trapezoid close to the base substrate 110 is not more than 90 degrees.

For example, as illustrated by FIG. 25, the length of the upper bottom of the trapezoidal cross section of the third sub-partition structure 743 is smaller than the length of the edge of the cross section of the first sub-partition structure 741 close to the base substrate 110.

For example, the side edge of the third sub-partition structure 743 may be a straight edge or a curved edge. For example, the curved edge bends to the side thereof away from the center of the third sub-partition structure 743, or the curved edge bends to the side thereof close to the center of the third sub-partition structure 743. In this case, the included angle between the curved edge and the bottom edge of the third sub-partition structure 743 may refer to the included angle between the tangent at the midpoint of the curved edge and the bottom edge.

For example, the difference between forming the partition structure shown in FIG. 25 and forming the partition structure shown in FIG. 23 is that the inorganic nonmetallic material layer 030 is etched by the dry etching method to form the first sub-partition structure 741 and the second sub-partition structure 742, while the part of the organic material layer 180 directly below the first sub-partition structure 741 is dry etched to form the third sub-partition structure 743. For example, a mask may be used to shield the part of the inorganic nonmetallic material layer 030 at the position where the first sub-partition structures 741 and second sub-partition structures 742 are to be formed, so that the part of the inorganic nonmetallic material layer 030 at other positions other than the position where the first sub-partition structures 741 and second sub-partition structures 742 are to be formed is etched. In the process of dry etching the inorganic nonmetallic material layer 030, the etching gas can etch the part of the organic material layer 180 that is not covered by the mask plate, so that an organic material layer with a certain thickness (i.e. the third sub-partition structure 743) remains directly below the inorganic non-metallic material layer (i.e. the first sub-partition structure 741 and the second sub-partition structure 742) after etching, so that a protrusion located directly below the first sub-partition structure 741 and the second sub-partition structure 742 is formed on the side of the organic material layer 180 away from the base substrate 110. This example is not limited to this case. The first sub-partition structure 741 and the second sub-partition structure 742 may be formed by wet etching first, and then the third sub-partition structure 743 may be formed by dry etching; or, the first sub-partition structure 741, the second sub-partition structure 742 and the third sub-partition structure 743 are formed by dry etching first and then wet etching.

For example, as illustrated by FIGS. 22A and 22B, in the process of dry etching the inorganic nonmetallic material layer 030, the thickness of the organic material layer 180 may range from 100 angstroms to 10000 angstroms, and the thickness of the formed third sub-partition structure 743 may range from 100 angstroms to 10000 angstroms. For example, in the process of dry etching the inorganic nonmetallic material layer 030, the thickness of the organic material layer 180 may range from 200 angstroms to 2000 angstroms, and the thickness of the formed third sub-partition structure 743 may range from 200 angstroms to 2000 angstroms.

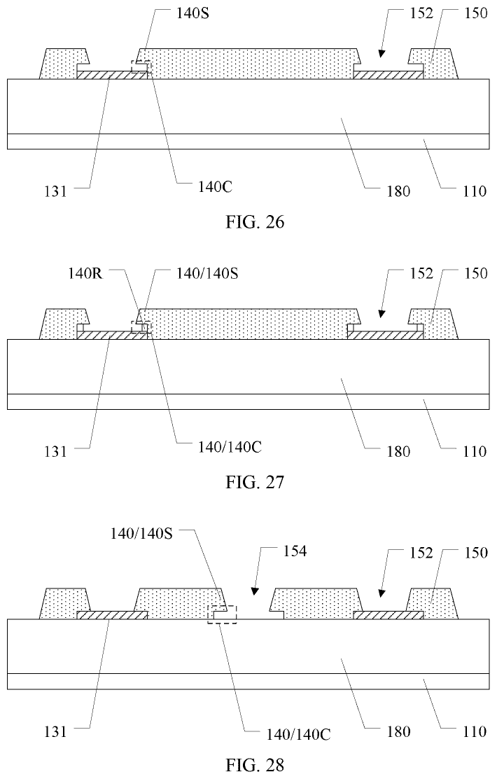

At least one embodiment of the present disclosure further provides a display substrate. FIG. 26 is a structural schematic diagram of further another display substrate provided by an embodiment of the present disclosure. As illustrated by FIG. 26, the display substrate 100 includes a base substrate 110 and a plurality of sub-pixels (not shown); a plurality of sub-pixels are located on the base substrate 110, and each sub-pixel includes a light-emitting element; each light-emitting element includes a light-emitting function layer, and a first electrode 131 and a second electrode (not shown) that are respectively located on two sides of the light-emitting function layer, and the first electrode 131 is located between the light-emitting function layer and the base substrate 110; at least part of the second electrode is located on the side of the light-emitting function layer away from the first electrode 131. It should be noted that the specific structures of sub-pixels, light-emitting elements and light-emitting function layers may be referred to FIG. 1 and FIG. 2, and are not repeated here in the present disclosure.

As illustrated by FIG. 26, the display substrate 100 further includes a pixel partition structure 140, and the pixel partition structure 140 is located on the base substrate 110 and between adjacent sub-pixels; at least one of a plurality of sub-functional films in the light-emitting function layer is disconnected at the position where the pixel partition structure 140 is located. The display substrate 100 further includes a pixel definition layer 150; part of the pixel definition layer 150 is located on the side of the first electrode 131 away from the base substrate 110; the pixel definition layer 150 includes a plurality of pixel openings 152; a plurality of pixel openings 152 are in one-to-one correspondence with a plurality of sub-pixels 200 to define effective light-emitting regions of the plurality of sub-pixels 200; the pixel opening 152 is configured to expose the first electrode 131 so that the first electrode 131 is in contact with the subsequently formed light-emitting function layer 120.

as illustrated by FIG. 26, the pixel partition structure 140 includes a concave structure 140C and a shielding part 140S, the concave structure 140C is located at the edge of the first electrode 131 and recessed into the pixel definition layer 150, and the shielding part 140S is located at the side of the groove 140C away from the base substrate 110 and is a part of the pixel definition layer 150. Therefore, the conductive sub-layer of the light-emitting function layer is disconnected at the position where the shielding part is located. Therefore, by arranging the pixel partition structure between adjacent sub-pixels, in the display substrate, crosstalk between adjacent sub-pixels caused by the sub-function layer with high conductivity among the light-emitting function layers can be avoided.

On the other hand, because the display substrate can avoid crosstalk between adjacent sub-pixels through the pixel partition structure, in the display substrate, the pixels per inch can be improved while a design of Tandem EL is adopted. Therefore, the display substrate has the advantages of long service life, low power consumption, high brightness and high resolution.

In some examples, as illustrated by FIG. 26, the orthographic projection of the concave structure 140C on the base substrate 110 overlaps with the orthographic projection of the shielding part 140S on the base substrate 110.

FIG. 27 is a structural schematic diagram of further another display substrate provided by an embodiment of the present disclosure. As illustrated by FIG. 27, the concave structure 140C includes a residual structure 140R located at the position of the concave structure 140 close to the pixel definition layer 150.

In some examples, as illustrated by FIG. 27, the material of the residual structure 140R includes a metal, such as silver.

An embodiment of the present disclosure further provides a display substrate. FIG. 28 is a structural schematic diagram of further another display substrate provided by an embodiment of the present disclosure. The display substrate shown in FIG. 28 provides another pixel partition structure. As illustrated by FIG. 28, the display substrate 100 further includes a pixel definition layer 150 located on the base substrate 110; part of the pixel definition layer 150 is located on the side of the first electrode 131 away from the base substrate 110; the pixel definition layer 150 includes a plurality of pixel openings 152 and a pixel spacing opening 154; plurality of pixel openings 152 are in one-to-one correspondence with a plurality of sub-pixels 200 to define effective light-emitting regions of the plurality of sub-pixels 200; the pixel opening 152 is configured to expose the first electrode 131 so that the first electrode 131 is in contact with the subsequently formed light-emitting function layer 120. The pixel spacing opening 154 is located between adjacent first electrodes 131, and at least part of the partition structure 140 is located in the pixel spacing opening 154.

As illustrated by FIG. 28, the pixel partition structure 140 includes a concave structure 140C and a shielding part 140S, the concave structure 140C is located at the edge of the pixel spacing opening 154 and is concave to the pixel definition layer 150. For example, the concave structure 140C may be concave to the pixel definition layer 150 in a direction parallel to the base substrate 110. The shielding part 140S is located at the side of the groove 140C away from the base substrate 110, and is a part of the pixel definition layer 150. Therefore, the conductive sub-layer of the light-emitting function layer is disconnected at the position where the shielding part is located. Therefore, by arranging the pixel partition structure between adjacent sub-pixels, in the display substrate, crosstalk between adjacent sub-pixels caused by the sub-function layer with high conductivity among the light-emitting function layers can be avoided.

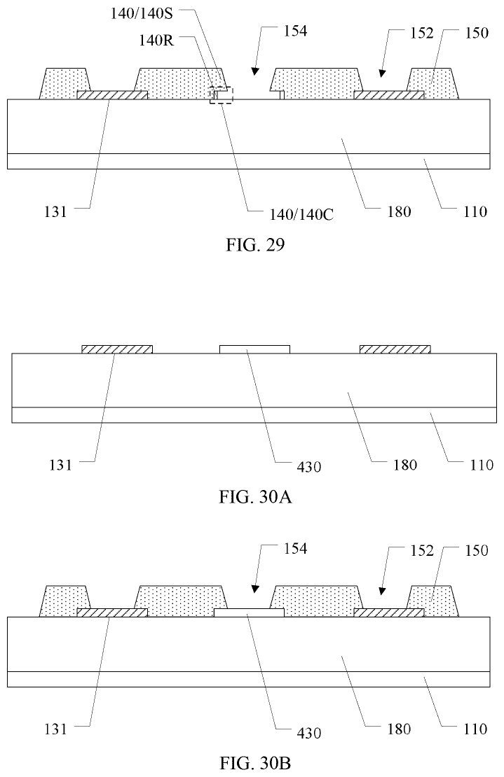

FIG. 29 is a structural diagram of further another display substrate provided by an embodiment of the present disclosure. As illustrated by FIG. 29, the concave structure 140C includes a residual structure 140R located at the position of the concave structure 140 close to the pixel definition layer 150.

In some examples, as illustrated by FIG. 29, the material of the residual structure 140R includes at least one selected from the group consisting of metal, metal oxide and organic substance; the metal may be silver, the metal oxide may be indium zinc oxide, and the organic substance may be amino polymer.

In some examples, in the case where the material of the residual structure 140R is an amino polymer, because the material of the planarization layer includes at least one selected from the group consisting of photoresist, polyimide (PI) resin, acrylic resin, silicon compound or polyacrylic resin. Therefore, the solvent of the planarization layer is mainly non-fluorinated organic solvent, although these photoresists may contain a small amount of fluorination, they are not basically soluble in fluorinated solution or perfluoro solvent. Therefore, their orthogonal characteristics can be utilized (the solution and solvent will not react with each other), so as to form the above pixel partition structure by an etching process.

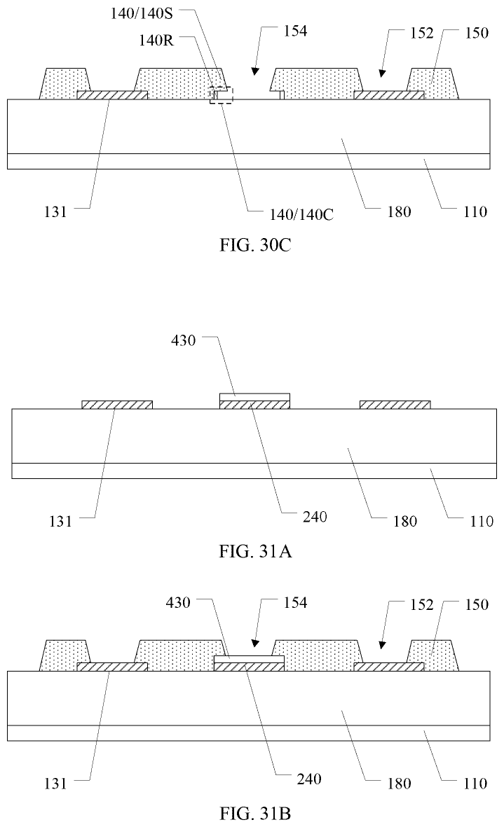

FIGS. 30A-30C are schematic steps of another manufacturing method of a display substrate provided by an embodiment of the present disclosure, and the manufacturing method of the display substrate comprises the following steps.

As illustrated by FIG. 30A, the first electrode 131 and the sacrifice structure 430 are formed on the side of the planarization layer 180 away from the base substrate 110. It should be noted that the above-mentioned residual structure may be a part of the sacrifice structure;

As illustrated by FIG. 30B, a pixel definition layer 150 is formed on the side of both the first electrode 131 and the sacrifice structure 430 away from the base substrate 110. The pixel definition layer 150 includes a plurality of pixel openings 152 and a pixel spacing opening 154; a plurality of pixel openings 152 are arranged in one-to-one correspondence with a plurality of first electrodes 131; the pixel opening 152 is configured to expose the first electrode 131 so that the first electrode 131 is in contact with the subsequently formed light-emitting function layer 120. The pixel spacing opening 154 is located between adjacent first electrodes 131, and a part of the sacrifice structure 430 is exposed by the pixel spacing opening 154.

As illustrated by FIG. 30C, the display substrate is etched with the pixel definition layer 150 as a mask to remove the sacrifice structure 430, so as to form the pixel partition structure 140.

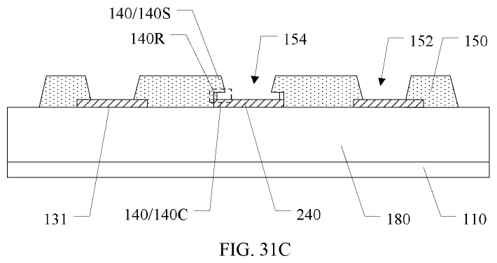

FIGS. 31A-31C are schematic steps of another manufacturing method of a display substrate provided by an embodiment of the present disclosure, and the manufacturing method of the display substrate includes the following steps.

As illustrated by FIG. 31A, the first electrode 131, the protection structure 240 and the sacrifice structure 430 are formed on the side of the planarization layer 180 away from the base substrate 110, and the protection structure 240 is arranged in the same layer as the first electrode 131. The material of the protection structure 240 is the same as that of the first electrode 131, and the material of the protection structure 240 is different from that of the sacrifice structure 430.

As illustrated by FIG. 31B, a pixel definition layer 150 is formed on the side of both the first electrode 131 and the sacrifice structure 430 away from the base substrate 110. The pixel definition layer 150 includes a plurality of pixel openings 152 and a pixel spacing opening 154; a plurality of pixel openings 152 are arranged in one-to-one correspondence with a plurality of first electrodes 131; the pixel opening 152 is configured to expose the first electrode 131, so that the first electrode 131 is in contact with the subsequently formed light-emitting function layer 120. The pixel spacing opening 154 is located between adjacent first electrodes 131, and a part of the sacrifice structure 430 is exposed by the pixel spacing opening 154.

As illustrated by FIG. 31C, the display substrate is etched with the pixel definition layer 150 as a mask to remove the sacrifice structure 430, so as to form the pixel partition structure 140.

It is to be noted that:
(1) In the drawings of the embodiments of the present disclosure, only the structures related to the embodiments of the present disclosure are involved, and other structures may refer to the common design(s).
(2) In case of no conflict, features in one embodiment or in different embodiments of the present disclosure can be combined.

The above is only the specific embodiment of this disclosure, but the protection scope of this disclosure is not limited thereto. Therefore, the scope of protection of this disclosure should be based on the scope of protection of the claims.

1. A display substrate comprising:
a base substrate; and
a plurality of sub-pixels, on the base substrate, wherein each of the plurality of sub-pixels comprises a light-emitting element, the light-emitting element comprises a light-emitting function layer, and a first electrode and a second electrode that are respectively on two sides of the light-emitting function layer, and the first electrode is between the light-emitting function layer and the base substrate,
wherein the display substrate further comprises a partition structure, located between two sub-pixels of the plurality of sub-pixels, the two sub-pixels are arranged adjacent to each other in a first direction.

2. The display substrate according to claim 1, wherein the light-emitting function layer comprises a conductive sub-layer, the partition structure comprises a plurality of annular partition parts, the plurality of sub-pixels comprises a plurality of first color sub-pixels, a plurality of second color sub-pixels and a plurality of third color sub-pixels, the plurality of annular partition parts comprise a plurality of first annular partition parts, a plurality of second annular partition parts, and a plurality of third annular partition parts, each of the plurality of first annular partition parts is around one of the plurality of second color sub-pixels, each of the plurality of second annular partition parts is around one of the plurality of first color sub-pixels, each of the plurality of third annular partition parts is around one of the plurality of third color sub-pixels.

3. The display substrate according to claim 2, wherein each of the plurality of first annular partition parts comprises a first number of first notches, each of the plurality of second annular partition parts comprises a second number of second notches, each of the plurality of third annular partition parts comprises a third number of third notches, the second number is different from the third number.

4. The display substrate according to claim 1, wherein the first number is equal to the second number.

5. The display substrate according to claim 1, wherein the partition structure comprises:
a first sub-partition structure; and
a second sub-partition structure,
wherein the first sub-partition structure and the second sub-partition structure are sequentially arranged in an arrangement direction of adjacent ones of the plurality of sub-pixels.

6. The display substrate according to claim 1, further comprising:
a pixel definition layer, on the base substrate,
wherein part of the pixel definition layer is on a side of the first electrode away from the base substrate, and the pixel definition layer comprises a plurality of pixel openings and a pixel spacing opening, wherein the plurality of pixel openings are in one-to-one correspondence to the plurality of sub-pixels to define effective light-emitting regions of the plurality of sub-pixels, and each of the plurality of pixel openings is configured to expose the first electrode,
the pixel spacing opening is between adjacent ones of the plurality of sub-pixels, and at least part of the partition structure is in the pixel spacing opening.

7. The display substrate according to claim 1, wherein each of the plurality of first annular partition parts comprises two first sub partition parts, each of the plurality of second annular partition parts comprises two second sub partition parts,
the two first sub partition parts are arranged around one of the plurality of second color sub-pixels, and the two second sub partition parts are arranged around one of the plurality of first color sub-pixels.

8. The display substrate according to claim 1, wherein the first number and the second number both are two.

9. The display substrate according to claim 8, wherein a first virtual line extending in a second direction and passing through one first notch of the first notches is overlapped with one of the plurality of second annular partition parts,
a second virtual line extending in a first direction and passing through one second notch of the second notches is overlapped with one of the plurality of third annular partition parts.

10. The display substrate according to claim 9, wherein the first virtual line is overlapped with a second annular partition part of the plurality of second annular partition parts which is directly adjacent to the first notch,
the second virtual line is overlapped with a third annular partition part of the plurality of second annular partition parts which is directly adjacent to the second notch.

11. The display substrate according to claim 1, wherein the plurality of first color sub-pixels and the plurality of second color sub-pixels are alternately arranged along a second direction to form a plurality of first pixel columns, and the plurality of third color sub-pixels are arranged in the second direction to form a plurality of second pixel columns, the plurality of first pixel columns and the plurality of second pixel columns are alternately arranged along the first direction,
the partition structure is between one of the plurality of first color sub-pixels and one of the plurality of third color sub-pixels that are adjacent to each other, and/or, the partition structure is between one of the plurality of second color sub-pixels and one of the plurality of third color sub-pixels that are adjacent to each other, and/or, between one of the plurality of first color sub-pixels and one of the plurality of second color sub-pixels that are adjacent to each other.

12. The display substrate according to claim 11, wherein two third color sub-pixels of the plurality of third color sub-pixels, which are directly adjacent to each other, include a first gap therebetween,
in one of the plurality of first pixel columns, a first color sub-pixel and a second color sub-pixel, which are directly adjacent to each other, include a second gap therebetween,
the first gap is larger than the second gap.

13. The display substrate according to claim 12, wherein a third virtual line extending in the first direction and passing through the second gap is overlapped with one of the plurality of third color sub-pixels.

14. The display substrate according to claim 12, wherein a size of each of the plurality of third color sub-pixels in the second direction is larger than a size of each of the plurality of first color sub-pixels in the second direction.

15. The display substrate according to claim 1, wherein the light-emitting function layer comprises a first light-emitting layer and a second light-emitting layer that are respectively on two sides of the conductive sub-layer in a direction perpendicular to the base substrate, and the conductive sub-layer is a charge generation layer.

16. The display substrate according to claim 5, further comprises:
a groove,
wherein a first light-emitting layer structure, a charge generation layer structure and a second light-emitting layer structure are arranged in the groove.

17. The display substrate according to claim 16, wherein an electrode structure is further provided in the groove, a distance from an upper surface of the electrode structure to the base substrate is smaller than a distance from a lower surface of the first electrode to the base substrate.

18. The display substrate according to claim 5, wherein a transition region is provided between the groove and one pixel opening of the plurality of pixel openings, a distance from an upper surface of the second electrode in the transition region to the base substrate is larger than a distance from an upper surface of the second electrode in the pixel opening to the base substrate,
the distance from the upper surface of the second electrode in the pixel opening to the base substrate is larger than the distance from the upper surface of the electrode structure to the base substrate.

19. The display substrate according to claim 1, further comprising:
a planarization layer, at a side of the first electrode close to the base substrate;
a plurality of data lines, between the planarization layer and the base substrate, wherein the data lines extend along a first direction and arranged along a second direction, and the first direction intersect the second direction;
a plurality of power lines, between the planarization layer and the base substrate, wherein the plurality of power lines extend along the first direction and are arranged in the second direction, and
the partition structure overlaps, in the direction perpendicular to the base substrate, with at least one of the data line and the power line.

20. A display device comprising the display substrate according to claim 1.
